(19) United States
(12) Patent Application Publication
(10) Pub. No.: US 2026/0006933 A1
(43) Pub. Date: Jan. 1, 2026

(54) IMAGE SENSOR

(71) Applicant: Samsung Electronics Co., Ltd., Suwon-si (KR)

(72) Inventors: Mintae CHUNG, Suwon-si (KR); Donghyun KIM, Suwon-si (KR); Dong-Chul LEE, Suwon-si (KR); Tae-Hun LEE, Suwon-si (KR); Sungsoo CHOI, Suwon-si (KR)

(73) Assignee: Samsung Electronics Co., Ltd., Suwon-si (KR)

(21) Appl. No.: 18/988,162

(22) Filed: Dec. 19, 2024

(30) Foreign Application Priority Data
Jun. 27, 2024 (KR) 10-2024-0084847

(51) Int. Cl. H10F 39/00

(52) U.S. Cl. CPC H10F 39/811; H10F 39/802

(57) ABSTRACT

An image sensor may include a substrate and a plurality of pixel regions. At least one of the plurality of pixel regions includes a photoelectric conversion portion in the substrate and a pixel circuit adjacent to the first surface of the substrate. The pixel circuit may include a plurality of buried patterns, which each may have a buried structure in the substrate. The pixel circuit may include a first transistor including a first gate electrode and a second transistor including a second gate electrode. The first gate electrode may be a vertical transfer gate electrode. A cross-sectional shape of the second gate electrode may be different from a cross-sectional shape of the first gate electrode. The plurality of buried patterns may include the first gate electrode and the second gate electrode.

### CROSS-REFERENCE TO RELATED APPLICATION

This application claims priority to and the benefit of Korean Patent Application No. 10-2024-0084847 filed in the Korean Intellectual Property Office on Jun. 27, 2024, the entire contents of which are incorporated herein by reference.

### BACKGROUND

### (a) Field

The present disclosure relates to an image sensor, and more particularly, to an image sensor having an improved and/or enhanced structure.

### (b) Description of the Related Art

An image sensor may be a semiconductor device that converts optical images into electrical signals. The image sensors may be classified into charge coupled device (CCD) type image sensors based on silicon semiconductors and complementary metal oxide semiconductor (CMOS) type image sensors (CIS).

Among these, the CMOS type image sensor may be driven by a simple method and a signal processing circuit may be integrated on a single chip in the CMOS type image sensor. Therefore, the CMOS type image sensor may be downsized and/or have a low power consumption, and thus, may be applied to products with a limited battery capacity. With the advancement of the electronics industry, various studies are continuing to improve the performance of the CMOS type image sensors.

### SUMMARY

The present disclosure may provide an image sensor capable of enhancing efficiency and/or productivity.

An image sensor according to an embodiment may include a substrate including a first surface and a second surface opposite each other; and a plurality of pixel regions. At least one of the plurality of pixel regions includes a photoelectric conversion portion in the substrate and a pixel circuit adjacent to the first surface of the substrate. The pixel circuit may include a plurality of buried patterns. Each of the plurality of buried patterns may have a buried structure in the substrate. The pixel circuit may include a first transistor and a second transistor. The first transistor may include a first gate electrode and the second transistor may include a second gate electrode. The first gate electrode may be a vertical transfer gate electrode. A cross-sectional shape of the second gate electrode may be different from a cross-sectional shape of the first gate electrode. The plurality of buried patterns may include the first gate electrode and the second gate electrode.

An image sensor according to an embodiment may include a substrate including a first surface and a second surface opposite each other; and a plurality of pixel regions. At least one of the plurality of pixel regions includes a photoelectric conversion portion in the substrate and a pixel circuit adjacent to the first surface of the substrate. The pixel circuit may include a plurality of buried patterns. Each of the plurality of buried patterns may have a buried structure in the substrate. The pixel circuit may include a first transistor, a second transistor, and a connection pattern. The first transistor may include a first gate electrode. The second transistor may include a second gate electrode. A cross-sectional shape of the second gate electrode may be different from a cross-sectional shape of the first gate electrode. The connection pattern may include at least one of a doping connection pattern or a wiring pattern. The plurality of buried patterns may include the second gate electrode and the connection pattern.

An image sensor according to an embodiment may include a substrate including a first surface and a second surface opposite each other; a plurality of pixel regions; and an isolation portion disposed to correspond to a boundary of the plurality of pixel regions. At least one of the plurality of pixel regions includes a photoelectric conversion portion in the substrate and a pixel circuit adjacent to the first surface of the substrate. The pixel circuit may include a doping connection pattern. The doping connection pattern may have a buried structure in the substrate and may be connected to the substrate or a doping region in the substrate. The doping connection pattern may be in at least two pixel regions of the plurality of pixel regions. A portion of the doping connection pattern may be on the isolation portion.

According to an embodiment, a first transistor, a second transistor, and/or a connection pattern having different structures may be provided together at a substrate, and a number of processes may be reduced and/or manufacturing cost may be reduced. The first transistor, the second transistor, and/or the connection pattern may have a buried structure and thus a pixel circuit may be formed by an easier process and/or an electrical resistance may be reduced by reducing a depth of a first contact via. The connection pattern may be shared in a plurality of pixel regions and thus a number of the first contact vias and an area (e.g. a planar area) of the first wiring layer may be reduced and/or an interval between the first contact vias may increase, thereby reducing a parasitic capacitance. By reducing the parasitic capacitance, conversion gain may be improved.

Accordingly, efficiency and/or productivity of an image sensor may be improved and/or enhanced.

### BRIEF DESCRIPTION OF THE DRAWINGS

FIG. 1 is a block diagram that schematically illustrates an example of an image sensor.

FIG. 2 is a partial cross-sectional view that illustrates an image sensor according to an embodiment.

FIG. 3 is a plan view that schematically illustrates a substrate included in the image sensor illustrated in FIG. 2.

FIG. 4 is an enlarged view that illustrates a portion D of FIG. 2.

FIG. 5 is an enlarged view that illustrates a portion E of FIG. 2.

FIG. 6 is a plan view that schematically illustrates a partial portion of a photoelectric conversion substrate included in the image sensor illustrated in FIG. 2.

FIG. 7 to FIG. 18 are cross-sectional views that schematically illustrate a manufacturing method of an image sensor according to an embodiment.

FIG. 19 to FIG. 24 are cross-sectional views that schematically illustrate a manufacturing method of an image sensor according to an embodiment.

FIG. 25 is a plan view that schematically illustrates a substrate included in an image sensor according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, or so on, illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or so on, may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

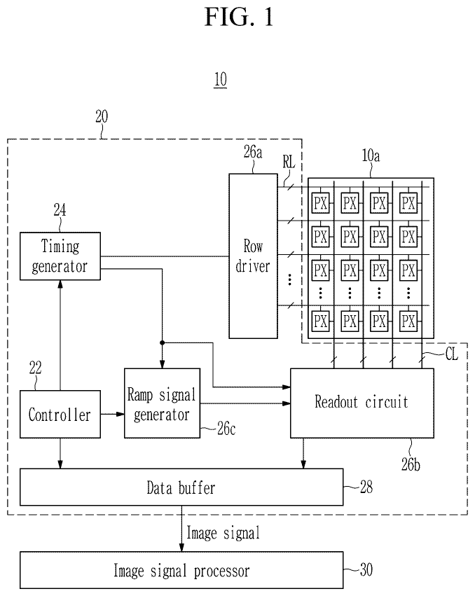

Hereinafter, an image sensor according to an embodiment and manufacturing methods of the same will be described in detail with reference to FIG. 1 to FIG. 24.

FIG. 1 is a block diagram that schematically illustrates an example of an image sensor 10.

Referring to FIG. 1, an image sensor 10 according to an embodiment may include a pixel array 10a, and a logic circuit 20 that controls the pixel array 10a. The logic circuit 20 is a circuit configured to control the pixel array 10a and may include, for example, a controller 22, a timing generator 24, a row driver 26a, a readout circuit 26b, a ramp signal generator 26c, and a data buffer 28. The image sensor 10 may further include an image signal processor 30. In some embodiments, the image signal processor 30 may be disposed outside the image sensor 10.

The image sensor 10 may generate an image signal by converting light received from the outside into an electric signal, and the image signal generated by the image sensor 10 may be provided to the image signal processor 30.

The image sensor 10 may be mounted on an electronic device with an image or light sensing function. For example, the image sensor 10 may be mounted on electronic devices such as cameras, smartphones, wearable devices, internet of things (IoT) devices, home appliance devices, tablets, personal digital assistants (PDA), portable multimedia players (PMP), navigations, drones, or advanced driver assistance systems (ADAS). In some embodiments, the image sensor 10 may be mounted on a vehicle, a furniture, a manufacturing facility, a door, or an electronic device provided as a part of various measuring devices.

The pixel array 10a may include a plurality of pixel regions PX, and a plurality of row lines RL and a plurality of column lines CL respectively connected to the plurality of pixel regions PX.

In an embodiment, each pixel region PX may include at least one photoelectric conversion device. The photoelectric conversion device may detect incident light and convert the incident light into the electric signal, that is, a plurality of analog pixel signals, according to an amount of light. The photoelectric conversion device may be a photodiode or a pinned diode. In some embodiments, the photoelectric conversion device may be a single-photon avalanche diode (SPAD) applied to a 3D sensor pixel. The level of the analog pixel signal output from the photoelectric conversion device may be proportional to the amount of light provided to each pixel region PX or the amount of charges output from the photoelectric conversion device.

The plurality of row lines RL may extend in one direction and be connected to the plurality of pixel regions PX arranged in the one direction. For example, a control signal output from the row driver 26a to the row line RL may be transmitted to a gate of a transistor of the plurality of pixel regions PX connected to the row line RL. The column line CL may extend in a crossing direction that is transverse to or crosses the one direction and may be connected to the plurality of pixel regions PX arranged in the crossing direction. The plurality of pixel signals output from the plurality of pixel regions PX may be transmitted to the readout circuit 26b through the plurality of column lines CL.

In an embodiment, the plurality of pixel regions PX may be grouped in a form of a plurality of columns and a plurality of rows to form one unit pixel group. That is, a plurality of pixel regions PX arranged in an extension direction of the row line RL and a plurality of pixel regions PX arranged in an extension direction of the column line CL may form one unit pixel group. For example, one unit pixel group may include a plurality of pixels arranged in the form of two columns and two rows, and one unit pixel group may output one analog pixel signal. However, example embodiments are not limited thereto and various modifications are possible.

In an embodiment, each pixel region PX may include a pixel circuit that processes the charge generated by the photoelectric conversion device and outputs the electric signal. The pixel circuit may include a transfer transistor, a reset transistor, a selection transistor, a source follower transistor, or so on. Example embodiments are not limited thereto and the pixel circuit may have any of various structures.

The controller 22 may generally control the timing generator 24, the row driver 26a, the readout circuit 26b, the ramp signal generator 26c, and the data buffer 28 included in the image sensor 10. For example, the controller 22 may control an operation timing by using a control signal. In an embodiment, the controller 22 may receive a mode signal indicating an imaging mode from an application processor and generally control the image sensor 10 based on the received mode signal.

The timing generator 24 may generate a signal that serves as a reference for the operation timing of the image sensor 10. The timing generator 24 may provide a control signal that controls the timing of the row driver 26a, the readout circuit 26b, and the ramp signal generator 26c.

The row driver 26a may generate a control signal to drive the pixel array 10a in response to the control signal of the timing generator 24, and may provide the control signal to the plurality of pixel regions PX of the pixel array 10a through the plurality of row lines RL. For example, the row driver 26a may generate a transfer signal that controls the transfer transistor, a reset control signal that controls the reset transistor, and a selection control signal that controls the selection transistor, and provide the transfer signal, the reset control signal, and the selection signal to the pixel array 10a.

The readout circuit 26b may convert a pixel signal (or an electric signal) output through the corresponding column line CL into a pixel value representing the amount of light. The ramp signal generator 26c may generate a reference signal or a ramp signal and transmit the reference signal or the ramp signal to the readout circuit 26b. For example, the readout circuit 26b may convert the pixel signal to the pixel value by comparing the ramp signal and the pixel signal. The pixel value may be an image data with a plurality of bits.

The data buffer 28 may store the pixel value of the pixel region PX transmitted from the readout circuit 26b and may output the stored pixel value in response to a signal from the controller 22.

The image signal processor 30 may perform an image signal processing on the image signal received from the data buffer 28. For example, the image signal processor 30 may receive a plurality of image signals from the data buffer 28 and generate one image by combining the received image signals.

Example embodiments are not limited to the above descriptions, and a structure, a type, or so on of the image sensor 10 may be variously modified.

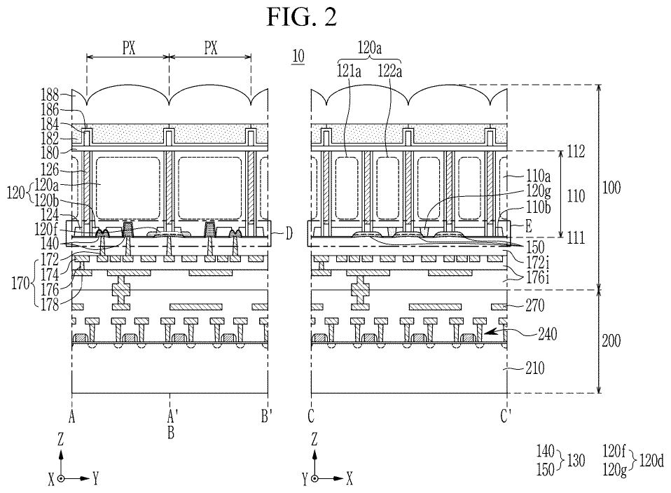

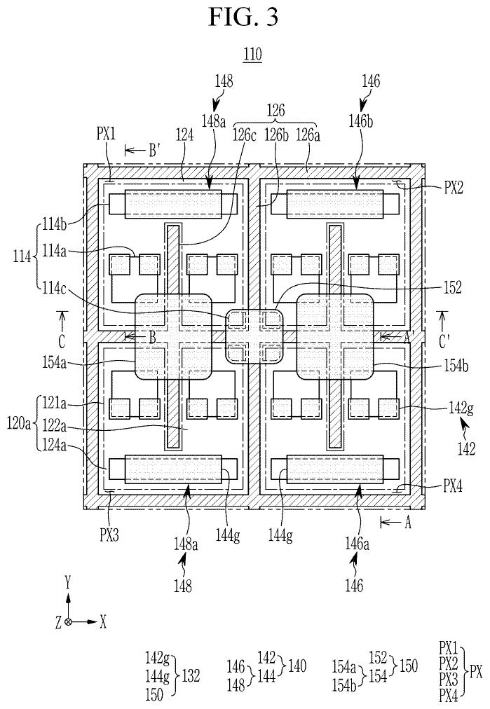

FIG. 2 is a partial cross-sectional view that illustrates an image sensor 10 according to an embodiment. FIG. 3 is a plan view that schematically illustrates a substrate 110 included in the image sensor 10 illustrated in FIG. 2. FIG. 2 is a cross-sectional view taken along a line A-A′, a line B-B′, and a line C-C′ of FIG. 3. FIG. 3 is a rear plan view illustrated based on a first surface 111 of the substrate 110 adjacent to a wiring portion 170. For a clearer understanding and a simpler illustration, a surface insulation layer 110b is omitted in FIG. 3.

Referring to FIG. 2 and FIG. 3, an image sensor 10 according to an embodiment may include a substrate 110 and a plurality of pixel regions PX. At least one of the plurality of pixel regions PX includes a photoelectric conversion portion 120 and a pixel circuit 130 adjacent to a first surface 111 of the substrate 110. The image sensor 10 or the substrate 110 may include an isolation portion 126 disposed to correspond to a boundary of the plurality of pixel regions PX. The photoelectric conversion portion 120 may be disposed in the substrate 110. The pixel circuit 130 may be disposed in the plurality of pixel regions PX at a portion adjacent to the first surface 111 of the substrate 110. The pixel circuit 130 may include a plurality of buried patterns 132, and each of the plurality of buried patterns 132 may have a buried structure that is buried in or inside the substrate 110.

In an embodiment, the substrate 110 may include a semiconductor substrate 110a that includes or is formed of a semiconductor material. For example, the semiconductor substrate 110a may include a bulk substrate that includes or is formed of a semiconductor material, a substrate that includes a bulk substrate and an epitaxial layer on the bulk substrate, or a semiconductor-on-insulator. In this instance, the semiconductor material included in the semiconductor substrate 110a may include a first conductivity type dopant to have a first conductivity type (e.g., a p-type or an n-type).

The semiconductor material included in the semiconductor substrate 110a may include or be formed of at least one of a group IV semiconductor, a group III-V compound semiconductor, or a group II-VI compound semiconductor. For example, the semiconductor material that is included in the semiconductor substrate 110a may include or be formed of at least one of Si, Ge, SiGe, SiC, GaAs, InAs, GaP, InP, InSb, InGaAs, ZnTe, or CdS. For example, the bulk substrate may be a single-crystalline or polycrystalline semiconductor substrate and may include or be formed of Si, Ge, or SiGe. In some embodiments, the semiconductor-on-insulator may be a silicon-on-insulator (SOI), a germanium-on-insulator (GOI), or a silicon-germanium-on-insulator (SGOI).

A doping region 120d may be disposed in a portion adjacent to the first surface 111 of the substrate 110 (e.g., in a partial portion of the semiconductor substrate 110a adjacent to the first surface 111).

In an embodiment, the doping region 120d may include at least one of a floating diffusion region 120f or a ground region 120g. The floating diffusion region 120f may have a second conductivity type opposite to a conductivity type of the semiconductor substrate 110a, and charges generated by the photoelectric conversion portion 120 may be accumulated in the floating diffusion region 120f. The floating diffusion region 120f may be disposed in a partial portion of a first active region 114a. The ground region 120g may be disposed in a third active region 114c that is separately disposed from the floating diffusion region 120f and a plurality of transistors 140. The ground region 120g may have a first conductivity type the same as a conductivity type of the semiconductor substrate 110a, and may have a doping concentration higher than a doping concentration of the substrate 110 or a second conductivity type well 120a. A ground voltage may be applied to the ground region 120g. A position or so on of the floating diffusion region 120f or the ground region 120g will be described later in more detail.

In the drawing, it is illustrated as an example that the doping region 120d includes the floating diffusion region 120f and the ground region 120g. However, example embodiments are not limited thereto. In some embodiments, the floating diffusion region 120f and/or the ground region 120g may be omitted. In some embodiments, an additional doping region other than the floating diffusion region 120f and/or the ground region 120g may be further included.

In an embodiment, a surface insulation layer 110b may be further included. The surface insulation layer 110b may be disposed on a first surface of the semiconductor substrate 110a that is adjacent to the first surface 111 of the substrate 110. For example, the surface insulation layer 110b may cover a surface of the semiconductor substrate 110a, a surface of a device isolation portion 124, and/or a surface of the isolation portion 126 that is adjacent to the first surface 111 of the substrate 110. The surface insulation layer 110b may be an end point detection (EPD) layer. However, example embodiments are not limited thereto. In some embodiments, the substrate 110 may include or be formed of the semiconductor substrate 110a, and the surface insulation layer 110b may be omitted.

In an embodiment, the plurality of pixel regions PX may include a first pixel region PX1 and a second pixel region PX2, and may further include a third pixel region PX3 and a fourth pixel region PX4. The first pixel region PX1 and the second pixel region PX2 may be adjacent to each other in a first direction (an X-axis direction in the drawings). The third pixel region PX3 and the fourth pixel region PX4 may be adjacent to the first pixel region PX1 and the second pixel region PX2, respectively, in a second direction (a Y-axis direction in the drawings) that is transverse to or crosses the first direction. For example, the first pixel region PX1, the second pixel region PX2, the third pixel region PX3, and the fourth pixel region PX4 that are illustrated in FIG. 3 may constitute one unit pixel group, but example embodiments are not limited thereto.

The photoelectric conversion portion 120 may be configured to convert light to an electrical signal and may be disposed in the substrate 110.

The photoelectric conversion portion 120 may include a first conductivity type well 120b and a second conductivity type well 120a. The first conductivity type well 120b may include a first conductivity type dopant to have a first conductivity type (e.g., a p-type or an n-type). The second conductivity type well 120a may include a second conductivity type dopant to have a second conductivity type (e.g., an n-type or a p-type) that is opposite to a conductive type of the semiconductor substrate 110a. The first conductivity type well 120b may be formed by doping the first conductivity type dopant to a portion of the semiconductor substrate 110a that is adjacent to the first surface 111 of the substrate 110. In some embodiments, the first conductivity type well 120b may be formed of a portion of the semiconductor substrate 110a where the second conductivity type well 120a is not positioned. The second conductivity type well 120a may be formed by doping the second conductivity type dopant to the semiconductor substrate 110a. A photodiode may be constituted by a pn junction of the first conductivity type well 120b and the second conductivity type well 120a. The photoelectric conversion portion 120 may generate and accumulate charges in proportion to an amount of light provided to each pixel region PX. In some embodiments, the first conductivity type well 120b may be omitted.

The photoelectric conversion portions 120 may be disposed to correspond to each pixel region PX. For example, the isolation portion 126 may pass through or penetrate at least a partial portion of the substrate 110 between the plurality of pixel regions PX in the substrate 110. One or more photoelectric conversion portion 120 may be disposed in the substrate 110 in each of the plurality of pixel regions PX.

In an embodiment, in a cross-sectional view, the isolation portion 126 may pass through or penetrate at least a partial portion of the substrate 110 in a thickness direction. In a plan view, the isolation portion 126 may pass through or penetrate a partial portion (e.g., an inner portion) of the device isolation portion 124.

The isolation portion 126 may be disposed in a first trench that has a relatively large depth. For example, the first trench may be a deep trench (DT), and the isolation portion 126 may be a deep trench isolation (DTI). In an embodiment, the isolation portion 126 may include a front deep trench isolation (FDTI) that includes a portion adjacent to the first surface 111 of the substrate 110 and/or a back deep trench isolation (BDTI) that includes a portion adjacent to a second surface 112 of the substrate 110. In the drawing, it is illustrated as an example that the isolation portion 126 includes the front deep trench isolation and entirely penetrates the semiconductor substrate 110a, but example embodiments are not limited thereto.

In a plan view, the isolation portion 126 may include a first isolation portion 126a that extends in the first direction (the X-axis direction in the drawings) and a second isolation portion 126b that extends in the second direction (the Y-axis direction in the drawings). For example, in a plan view, the isolation portion 126 may have a lattice shape to correspond to the plurality of pixel regions PX. Thereby, in a plan view, each pixel region PX may be surrounded by a pair of first isolation portions 126a and a pair of second isolation portions 126b.

In an embodiment, the isolation portion 126 may further include an inner isolation portion 126c that extends from the first isolation portion 126a to an inside of the pixel region PX. The inner isolation portion 126c may separate, divide, or define first and second portions 121a and 122a of the second conductivity type well 120a in the pixel region PX. However, example embodiments are not limited thereto. In some embodiments, the inner isolation portion 126c may be omitted.

The isolation portion 126 may include an insulation layer. The insulation layer of the isolation portion 126 may include or be formed of at least one of silicon oxide, silicon nitride, or silicon oxynitride, and may include a single layer or a plurality of layers. However, example embodiments are not limited thereto. A material of the insulation layer of the isolation portion 126 may be variously modified.

In an embodiment, the isolation portion 126 may further include a conductive layer. For example, the conductive layer of the isolation portion 126 may include or be formed of a semiconductor material (e.g., silicon). A dark current may be improved through a hole accumulation induced by a negative voltage applied to the conductive layer of the isolation portion 126. However, example embodiments are not limited thereto. The negative voltage might not be applied to the conductive layer of the isolation portion 126, or the isolation portion 126 might not include the conductive layer.

A sidewall doping region may be disposed at a portion of the semiconductor substrate 110a that is adjacent to the isolation portion 126. Sidewall doping regions may be disposed at portions adjacent to both sidewalls of the isolation portion 126, respectively. The sidewall doping region may improve the dark current, together with the conductive layer of the isolation portion 126. The sidewall doping region may have the first conductivity type (the p-type or the n-type) that is the same as a conductivity type of the semiconductor substrate 110a. For example, the sidewall doping region may have the p-type. For example, the sidewall doping region may include boron, aluminum, gallium, indium, or so on as a p-type dopant.

In each pixel region PX, the photoelectric conversion portion 120 (e.g., the second conductivity type well 120a) may be formed of a single portion or may include a plurality of portions. In FIG. 3, it is illustrated as an example that, in the pixel region PX, the second conductivity type well 120a includes first and second portions 121a and 122a that are spaced apart from each other, and a connection portion 124a that connects the first portion 121a and the second portion 122a. However, example embodiments are not limited thereto. In some embodiments, the second conductivity type well 120a may include three or more portion that are spaced apart from each other, the connection portion 124a may be positioned in another position, or the connection portion 124a may be omitted.

In an embodiment, the device isolation portion 124 may be disposed in a second trench that has a relatively small depth to separate, divide, or define the active region 114 in each pixel region PX. For example, the second trench may be a shallow trench (ST), and the device isolation portion 124 may be a shallow trench isolation (STI). In a cross-sectional view, the device isolation portion 124 may define the active region 114 in a portion adjacent to the first surface 111 of the substrate 110. In the drawings, a boundary of the device isolation portion 124 and the isolation portion 126 is illustrated for a clearer understanding. However, in some embodiments, the boundary of the device isolation portion 124 and the isolation portion 126 may not be confirmed and the device isolation portion 124 and the isolation portion 126 may form an integral structure at a portion adjacent to first surface 111 of the substrate 110.

In a plan view, the device isolation portion 124 may be disposed in a region other than the active region 114. In an embodiment, the active region 114 may include a first active region 114a that is included in a first transistor 142, a second active region 114b that is included in a second transistor 144, and a third active region 114c in which the ground region 120g is disposed.

The device isolation portion 124 may include or be formed of at least one of silicon oxide, silicon nitride, or silicon oxynitride, and the device isolation portion 124 may include a single layer or a plurality of layers. However, example embodiments are not limited thereto. Therefore, a material of the device isolation portion 124 may be variously modified, or the device isolation portion 124 may be omitted.

In FIG. 2, it is illustrated as an example that a surface of the device isolation portion 124 and a surface of the isolation portion 126, which are adjacent to the first surface of the semiconductor substrate 110a adjacent to the first surface 111 of the substrate 110, are disposed on the same plane as the first surface of the semiconductor substrate 110a. However, example embodiments are not limited thereto. The first surface of the semiconductor substrate 110a may be disposed on a different plane from the surface of the device isolation portion 124 and/or the surface the isolation portion 126.

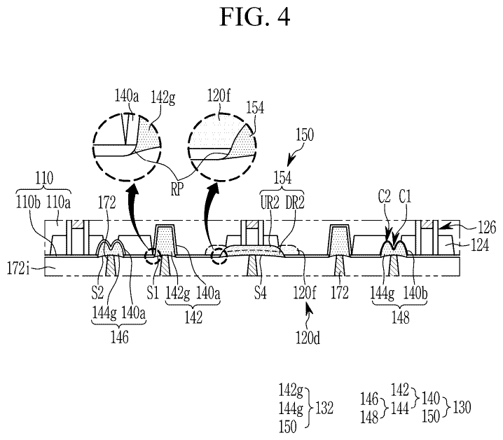

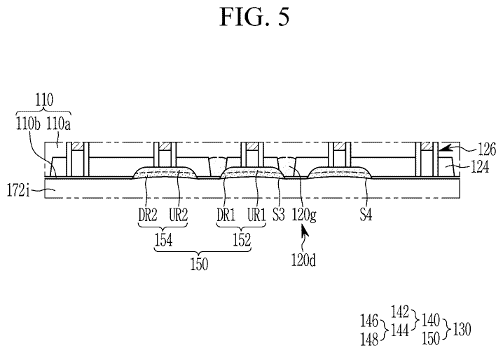

The pixel circuit 130 may be disposed to be adjacent to the first surface 111 of the substrate 110. The pixel circuit 130 will be described later in more detail with reference to FIG. 4 and FIG. 5.

The wiring portion 170 may be electrically connected to the pixel circuit 130 and may be disposed on the first surface 111 of the substrate 110. That is, the wiring portion 170 may be disposed to be adjacent to the first surface 111 of the substrate 110, which is opposite to the second surface 112 of the substrate 110 to which the light is incident, and thus, the wiring portion 170 might not be disposed in a path of the light incident to the image sensor 10. Thereby, light interference caused by the wiring portion 170 may be limited and/or minimized.

The wiring portion 170 may include a first contact via 172, a first wiring layer 174, and one or a plurality of second contact vias 176 and/or one or a plurality of second wiring layers 178. The first contact via 172 may pass through or penetrate the first interlayer insulation layer 172i to be connected (e.g. electrically connected) to the pixel circuit 130. The first wiring layer 174 may be connected (e.g. electrically connected) to the first contact via 172. The one or plurality of second contact vias 176 and/or the one or plurality of second wiring layers 178 may be disposed on the first wiring layer 174. The second contact via 176 may pass through or penetrate a second interlayer insulation layer 176i to connect (e.g., electrically connect) the first wiring layer 174 and the second wiring layer 178) or to connect (e.g., electrically connect) the second wiring layers 178 that are adjacent to each other. The first contact via 172, the first wiring layer 174, the second contact via 176, and the second wiring layer 178 of the wiring portion 170 may be connected to form a desired circuit. The first contact via 172 may be formed in the same process as the first wiring layer 174, or may be formed in a separate process from the first wiring layer 174. The second contact via 176 may be formed in the same process as the second wiring layer 178, or may be formed in a separate process from the second wiring layer 178.

The first interlayer insulation layer 172i or the second interlayer insulation layer 176i may include or be formed of an insulating material. For example, the first interlayer insulation layer 172i or the second interlayer insulation layer 176i may include or be formed of silicon oxide, silicon nitride, silicon oxynitride, and/or a low dielectric constant material. The low dielectric constant material may be a material having a dielectric constant lower than a dielectric constant of silicon oxide.

The first contact via 172, the first wiring layer 174, the second contact via 176, or the second wiring layer 178 may include or be formed of at least one of a metal, a metal alloy, metal nitride, metal silicide, or a doped semiconductor material. The metal or the metal alloy may include or be formed of at least one of tungsten, molybdenum, aluminum, copper, or cobalt, and the metal nitride may include or be formed of at least one of tungsten nitride, molybdenum nitride, titanium nitride, or tantalum nitride. The first contact via 172, the first wiring layer 174, the second contact via 176, or the second wiring layer 178 may further include metal oxide or metal oxynitride in which the above material is oxidized. The first contact via 172, the first wiring layer 174, the second contact via 176, or the second wiring layer 178 may include a single layer or a plurality of layers.

However, example embodiments are not limited thereto. The first interlayer insulation layer 172i or the second interlayer insulation layer 176i may include or be formed of any of various insulating materials, and the first contact via 172, the first wiring layer 174, the second contact via 176, or the second wiring layer 178 may include or be formed of any of various conductive materials.

A horizontal insulation layer 180, a color filter 182, a filter separator 184, a protection layer 186, and a micro lens 188 may be disposed on the second surface 112 of the substrate 110.

More particularly, the horizontal insulation layer 180 may be disposed on the second surface 112 of the substrate 110. The horizontal insulation layer 180 may be disposed to cover the second surface 112 of the substrate 110 and the isolation portion 126. The horizontal insulation layer 180 may act as a kind of a planarization layer configured to planarize a surface so that the color filter 182, the micro lens 188, or so on disposed on the horizontal insulation layer 180 may be stably formed.

The horizontal insulation layer 180 may include or be formed of any of various insulating materials. For example, the horizontal insulation layer 180 may include or be formed of oxide, nitride, oxynitride, or fluoride including at least one of hafnium, zirconium, aluminum, tantalum, titanium, yttrium, cerium, lanthanum, neodymium, praseodymium, ytterbium, or silicon. For example, the horizontal insulation layer 180 may act as an anti-reflection layer, but example embodiments are not limited thereto.

In an embodiment, the horizontal insulation layer 180 may include a plurality of layers including different materials and having different thicknesses. For example, in the horizontal insulation layer 180, a first horizontal insulation layer adjacent to the second surface 112 of the substrate 110 may be a fixed charge layer having a negative fixed charge. Thereby, the dark current may be improved by a hole accumulation at a periphery of the fixed charge layer. In an embodiment, the first horizontal insulation layer may include or be formed of metal oxide or metal fluoride including at least one of hafnium, zirconium, aluminum, tantalum, titanium, or yttrium. For example, the horizontal insulation layer 180 or the anti-reflection layer may include a first horizontal insulation layer including hafnium oxide, a second horizontal insulation layer including silicon oxide or silicon nitride, and a third horizontal insulation layer including hafnium oxide.

However, example embodiments are not limited to thereto, and a number, a thickness, or so on of layers included in the horizontal insulation layer 180 may be variously modified. In some embodiments, a structure configured to reflect light may be disposed at the second surface 112 of the substrate 110. For example, a nanoporous structure that has a nanometer-level size may be formed at the second surface 112 of the substrate 110 by using laser or etching, thereby reflecting the light. The nanometer-level size may refer to a size (e.g., an average width, an average diameter, or an average pitch) of less than 1 um. Thereby, the anti-reflection layer may be omitted in the horizontal insulation layer 180 and a manufacturing process may be simplified. However, example embodiments are not limited thereto. In some embodiments, when the structure configured to reflect the light is disposed at the second surface 112 of the substrate 110, the horizontal insulation layer 180 may include the anti-reflection layer.

The filter separator 184 may be disposed on the horizontal insulation layer 180. In an embodiment, the filter separator 184 may surround at least a partial portion of the color filter 182. For example, the filter separator 184 may have a lattice structure that is the same as or similar to the lattice structure of the isolation portion 126, but example embodiments are not limited thereto. The filter separator 184 may be referred to as a fence pattern or a grid pattern.

The filter separator 184 may limited and/or prevent light that is incident obliquely into one color filter 182 in one of the plurality of pixel regions PX from entering another color filter 182 in adjacent pixel region PX. Accordingly, a crosstalk between the plurality of pixel regions PX may be limited and/or prevented.

In an embodiment, the filter separator 184 may include a material having a refractive index smaller than a refractive index of the color filter 182 or silicon oxide, or a material having a refractive index of about 1.0 to about 1.4. When the filter separator 184 includes a material with a small refractive index in the above, the light incident on the filter separator 184 may be totally reflected and directed toward an inside of the pixel region PX.

For example, the filter separator 184 may include polymethyl methacrylate (PMMA), silicon acrylate, cellulose acetate butyrate (CAB), silica, or fluorine-silicon acrylate (FSA). For example, the filter separator 184 may include a polymer material in which silica particles are dispersed. However, example embodiments are not limited to thereto, and the filter separator 184 may include a material different from the above material.

The color filter 182 may be disposed on the horizontal insulation layer 180. The plurality of color filters 182 may be separated from each other by the filter separator 184. A plurality of color filters 182 may include, for example, a green filter, a blue filter, and a red filter. In some embodiments, the plurality of color filters 182 may include a cyan filter, a magenta filter, a yellow filter, an infrared filter for transmitting infrared light, or so on. In some embodiment, a pixel region PX where all visible light is incident may be provided.

The protection layer 186 may be disposed on the color filter 182 and/or the filter separator 184. The protection layer 186 may include or be formed of any of various materials such as an organic material, silicon oxide, silicon oxynitride, aluminum oxide, or so on. However, example embodiments are not limited to a material of the protection layer 186, and the protection layer 186 may be omitted.

The micro lens 188 that is disposed on the color filter 182 and/or the protection layer 186 may include or be formed of a portion having a convex shape to converge or concentrate light incident to the pixel region PX. The micro lens 188 may include or be formed of any or various resin materials, for example, a styrene-based resin, an acryl-based resin, a styrene-acryl copolymer resin, a siloxane-based resin, or so on.

However, example embodiments are not limited to thereto, and a shape, a material, or so on of the micro lens 188 may be variously modified. In some embodiments, a meta lens may be included instead of the micro lens 188. The meta lens may include a nano structure of a nano rod or a nano pillar that has a nanometer-level size. In the meta lens, by a meta surface including meta atoms that are smaller than a wavelength of light uniformly or periodically, a direction of incident light may be changed so that the light reach a specific point. Thereby, the meta lens may act as a lens. The meta lens or the nano structure may include or be formed of Si, SiN, GaN, TiO₂, or so on.

In the drawing, it is illustrated as an example that a plurality of micro lens 188 correspond to a plurality of pixel regions PX, respectively. However, example embodiments are not limited to thereto, and one micro lens 188 may correspond to a plurality of pixel regions PX. In some embodiments, an outer protection layer or so on may be further disposed on an outer surface of the micro lens 188.

In an embodiment, in a plan view, a relative position between the pixel region PX and the color filter 182 and/or a relative position between the pixel region PX and the micro lens 188 may be different from each other in a central portion of the image sensor 10 and in an edge portion of the image sensor 10. That is, in a plan view, an area (e.g. a planar area) of the color filter 182 that overlaps the pixel region PX and/or an area (e.g. a planar area) of the micro lens 188 that overlaps the pixel region PX may be smaller in the edge region of the image sensor 10 than in the central region of the image sensor 10. For example, an area (e.g. a planar area) of the color filter 182 that overlaps the pixel region PX and/or an area (e.g. a planar area) of the micro lens 188 that overlaps the pixel region PX may decrease from the central region of the image sensor 10 to the edge region of the image sensor 10.

By adjusting the relative position between the pixel region PX and the color filter 182 and/or the relative position between the pixel region PX and the micro lens 188, an amount of the light that reaches the photoelectric conversion portion 120 of the pixel region PX may be maximized. For example, the micro lens 188, the color filter 182, and the photoelectric conversion portion 120 of the pixel region PX may be disposed to be overlapped in a direction where light passes. Since the light is incident obliquely in the edge region of the image sensor 10, the relative position between the pixel region PX and the color filter 182 and/or the relative position between the pixel region PX and the micro lens 188 may be adjusted so that the light that is incident obliquely reaches the photoelectric conversion portion 120 of the pixel region PX to a large amount.

An additional wiring portion 200 may be further disposed on a photoelectric conversion substrate 100 (e.g., the wiring portion 170). The additional wiring portion 200 may include a semiconductor substrate 210, and a logic circuit portion, a power supply portion, or so on that includes a transistor 240, a wiring 270, or so on. The transistor 240 included in the additional wiring portion 200 may have a structure different from structures of the plurality of transistors 140 included in the photoelectric conversion substrate 100. For example, the transistor 240 of the additional wiring portion 200 may have a planar structure in which a gate insulation layer and a gate electrode are disposed on the substrate 210. The wiring 270 of the additional wiring portion 200 may include an interlayer insulation layer, a wiring layer, a contact via, or so on. The description to the first or second interlayer insulation layer 172i or 176i, the first or second wiring layer 174 or 178, or the first or second contact via 172 or 176 included in the wiring portion 170 may be applied to an interlayer insulation layer, a wiring layer, or a contact via included in the wiring 270 of the additional wiring portion 200. However, example embodiments are not limited thereto, and a member included in the additional wiring portion 200 may be variously modified.

In the image sensor 10 according to an embodiment, the light incident from an outside may be converged or concentrated by the micro lens 188 and incident on the photoelectric conversion portion 120 through the color filter 182. The light incident on the photoelectric conversion portion 120 may be converted into an electric signal according to an amount of the light.

Referring to FIG. 4 and FIG. 5 together with FIG. 2 and FIG. 3, examples of the pixel circuit 130 including the plurality of buried patterns 132 will be described in more detail.

FIG. 4 is an enlarged view that illustrates a portion D of FIG. 2. FIG. 5 is an enlarged view that illustrates a portion E of FIG. 2.

Referring to FIG. 2 to FIG. 5, in an embodiment, the pixel circuit 130 may be disposed to be adjacent to the first surface 111 of the substrate 110. In a plan view, the pixel circuit 130 may be disposed in the pixel region PX, on the isolation portion 126 and/or the device isolation portion 124, or in the active region 114.

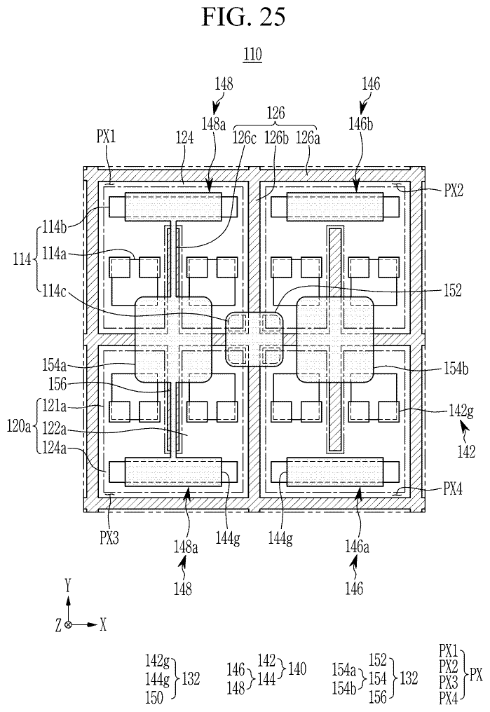

In an embodiment, the pixel circuit 130 may include a plurality of transistors 140 and/or a connection pattern 150. In this instance, the pixel circuit 130 may include a plurality of buried patterns 132, and each of the plurality of buried patterns 132 may have a buried structure buried in the substrate 110. The connection pattern 150 may be a portion other than the plurality of transistors 140. The connection pattern 150 may include a doping connection pattern (e.g., a first connection pattern 152 and/or a second connection pattern 154) that is connected to the substrate 110 or the doping region 120d, a wiring pattern that is connected to the plurality of transistors 140 and/or the doping connection pattern, or so on. The wiring pattern will be described in more detail later with reference to FIG. 25.

In an embodiment, the plurality of transistors 140 may include a first transistor 142 and a second transistor 144. The first transistor 142 may include a first gate electrode 142g, which is a vertical transfer gate (VTG) electrode. The second transistor 144 may include a second gate electrode 144g that has a cross-sectional shape different from a cross-sectional shape of the first gate electrode 142g.

The first transistor 142 may be a transfer transistor that includes the first gate electrode 142g, which is the vertical transfer gate electrode. In an embodiment, the second transistor 144 may include a plurality of second transistors 144 that are provided on the plurality of pixel regions PX, respectively, and perform different operations. For example, the second transistor 144 may include a third transistor 146 and a fourth transistor 148. The third transistor 146 may include at least one of a reset transistor 146a or a selection transistor 146b, and the fourth transistor 148 may include a source follower transistor 148a.

The first transistor 142 may transfer charges generated by the photoelectric conversion portion 120 to the floating diffusion region 120f in response to a transfer signal that is applied to the first gate electrode 142g. The reset transistor 146a may reset charges that are accumulated in the floating diffusion region 120f when a reset control signal is applied. The selection transistor 146b may select the pixel region PX in response to a selection control signal. The source follower transistor 148a may generate a pixel signal according to the charges that are accumulated in the floating diffusion region 120f.

The first transistor 142 may be electrically connected to the photoelectric conversion portion 120 and may include the first gate electrode 142g. In a cross-sectional view, the first gate electrode 142g, which is the vertical transfer gate electrode, may have a shape in which a length of the first gate electrode 142g is greater than a width of the first gate electrode 142g. The length of the first gate electrode 142g may be a length (e.g., a maximum length) in a thickness direction of the image sensor 10 (a Z-axis direction in the drawings). The width of the first gate electrode 142g may be a width (e.g., a minimum width in the X-axis or Y-axis direction in the drawings) in a plan view. The first transistor 142 may further include a gate insulation layer (e.g., a first gate insulation layer 140a) that is disposed between the first gate electrode 142g and the substrate 110 (e.g., the semiconductor substrate 110a).

In FIG. 3, an example is illustrated where one first active region 114a is provided to correspond to the first portion 121a of the second conductivity type well 120a, and another first active region 114a is provided to correspond to the second portion 122a of the second conductivity type well 120a. In FIG. 3, a dual vertical transfer gate structure is illustrated as an example. In the dual vertical transfer gate structure, two first gate electrodes 142g are connected to one first active region 114a. Thereby, charges generated in the photoelectric conversion portion 120 may be more effectively transferred. For a clearer understanding, in FIG. 3, an example is illustrated where two first gate electrodes 142g connected to one first active region 114a are spaced apart from each other, but example embodiments are not limited thereto. In some embodiments, two first gate electrodes 142g connected to one first active region 114a may be connected to each other in a portion adjacent to the first surface 111 of the substrate 110. In some embodiments, one first gate electrodes 142g may be connected to one first active region 114a to have a single vertical transfer gate (single VTG) structure. Other various modifications are possible.

The second transistor 144 may have a different structure and/or shape from the first transistor 142. Having a different structure and/or shape may mean that an electrode, a layer, or a doped portion that is included in or related to one of the first and second transistors 142 and 144 is not included in or related to another one of the first and second transistors 142 and 144. Having a different structure or shape may mean that a position, an arrangement, or so on of electrodes, layers, or doped portions that are included in or related to the first and second transistors 142 and 144 are different. Having a different structure or shape may mean that cross-sectional structures or shapes of electrodes, layers, or doped portions that are included in or related to the first and second transistors 142 and 144 are different. That is, even when there is a difference in width, length, planar shape, or so on, the transistors may be regarded as the same structure or shape.

In an embodiment, the second transistor 144 may include the second gate electrode 144g, and source and drain regions disposed in the substrate 110 (e.g., the semiconductor substrate 110a) at both sides of the second gate electrode 144g. The second transistor 144 may further include a gate insulation layer (e.g., a first gate insulation layer 140a or a second gate insulation layer 140b) that is disposed between the second gate electrode 144g and the substrate 110.

In the plurality of pixel regions PX, the plurality of second gate electrodes 144g that are included in the plurality of second transistors 144 (e.g., the selection transistor 146b, the reset transistor 146a, and the source follower transistor 148a) may have the same cross-sectional structure or shape. Having the same cross-sectional structure or shape may mean that an electrode, a layer or a doped portion that is included in or related to one of the plurality of second gate electrodes 144g is included in or related to another one of the plurality of second gate electrodes 144g. Having the same structure or shape may mean that a position, an arrangement, or so on of electrodes, layers, or doped portions that are included in or related to the plurality of second gate electrodes 144g are the same. Having the same different structure or shape may mean that cross-sectional structures or shapes of electrodes, layers, or doped portions that are included in or related to the plurality of second gate electrodes 144g are the same. That is, even when there is a difference in width, length, planar shape, or so on, the second gate electrodes 144g may be regarded as having the same cross-sectional structure or shape.

In an embodiment, the second transistor 144 may be a three-dimensional (3D) transistor having a three dimensional structure or the second gate electrode 144g included in the second transistor 144 may be a three dimensional gate electrode having a three dimensional structure. For example, in a cross-sectional view that crosses (e.g., is perpendicular to) a length direction of the second transistor 144 or the second gate electrode 144g included in the second transistor 144, a depth change portion in which a depth is changed may be provided in an inner portion between both side portions. When the depth change portion is provided in the inner portion, a transistor width of the second transistor 144 may be greater than a width of the second gate electrode 144g (e.g., a width in the Y-axis direction, as an example, a minimum width) in a plan view. Thereby, properties of the second transistor 144 may be maintained and an area (e.g., a planar area) of the second transistor 144 may be reduced to be suitable for reducing a size of pixels.

For example, in a cross-sectional view, in the second gate electrode 144g of the second transistor 144, a concave portion C1 may be provided in a central portion to have a relatively small depth, and convex portions C2 may be provided between the central portion and the both side portions to have a relatively large depth. However, a shape of the second gate electrode 144g of the second transistor 144 illustrated in FIG. 4 is an example of the three dimensional structure, but example embodiments are not limited thereto. Accordingly, the second gate electrode 144g may have any of various structures that have cross-sectional shapes different from a cross-sectional shape of the first gate electrode 142g.

In an embodiment, the device isolation portions 124 may be disposed at both sides of the second gate electrode 144g of the second transistor 144. More particularly, in a crossing direction (the Y-axis direction in the drawings) that is transverse to or crosses the length direction (the X-axis direction in the drawings) of the second gate electrode 144g of the second transistor 144, the device isolation portions 124 may be disposed at both sides of the second gate electrode 144g of the second transistor 144. In a plan view, the device isolation portions 124 disposed at both sides of the second gate electrode 144g of the second transistor 144 may include a portion that extends in a direction parallel to the length direction of the second gate electrode 144g. Thereby, the second gate electrode 144g of the second transistor 144 that has the three dimensional structure may be easily formed. This will be described in more detail later in a manufacturing method.

In an embodiment, the first transistor 142 and the second transistor 144 are provided in each pixel region PX, and the plurality of second transistors 144 may be shared in the plurality of pixel regions PX that constitute one unit pixel group. For example, the first pixel region PX1, the second pixel region PX2, the third pixel region PX3, and the fourth pixel region PX4 illustrated in FIG. 3 may constitute one unit pixel group. The second transistor 144 in each of the first pixel region PX1 and the third pixel region PX3 may include the source follower transistor 148a, the second transistor 144 in the second pixel region PX2 may include the selection transistor 146b, and the second transistor 144 in the fourth pixel region PX4 may include the reset transistor 146a. However, example embodiments are not limited thereto, and various modifications are possible.

In an embodiment, the connection pattern 150 may include at least one of a first connection pattern 152 or a second connection pattern 154. The first connection pattern 152 may be electrically and/or physically connected to the ground region 120g. The second connection pattern 154 may be electrically and/or physically connected to the floating diffusion region 120f.

In each pixel region PX, the ground region 120g may be disposed in at least a partial portion of the third active region 114c that is adjacent to the first connection pattern 152. In each pixel region PX, one or a plurality of floating diffusion regions 120f may be disposed in at least a partial portion of the first active region 114a that is adjacent to the second connection pattern 154. For example, when the second conductivity type well 120a includes the first portion 121a and the second portion 122a, the floating diffusion region 120f may be disposed at least in a portion adjacent to the first connection pattern 152 in the first active region 114a corresponding to the first portion 121a, and the floating diffusion region 120f may be disposed at least in a portion adjacent to the first connection pattern 152 in the first active region 114a corresponding to the second portion 122a. In each pixel region PX, the floating diffusion region 120f may be disposed at least at one side of the first transistor 142 (e.g., the first gate electrode 142g).

The first connection pattern 152 and/or the second connection pattern 154 may be disposed in at least two pixel regions PX of the plurality of pixel regions PX, or at least a partial portion of the first connection pattern 152 and/or the second connection pattern 154 may be disposed on the isolation portion 126. That is, the first connection pattern 152 and/or the second connection pattern 154 may be shared in at least two pixel regions PX of the plurality of pixel regions PX.

In an embodiment, the first connection pattern 152 may be disposed in the first pixel region PX1, the second pixel region PX2, the third pixel region PX3, and the fourth pixel region PX4. The first connection pattern 152 may be connected to the plurality of ground regions 120g that are respectively disposed in the first pixel region PX1, the second pixel region PX2, the third pixel region PX3, and the fourth pixel region PX4.

For example, in a central portion of one unit pixel group that the first pixel region PX1, the second pixel region PX2, the third pixel region PX3, and the fourth pixel region PX4 are adjacent to each other, one first connection pattern 152 may be provided. In a plan view, the ground regions 120g may be adjacent to the central portion of one unit pixel group in each of the first pixel region PX1, the second pixel region PX2, the third pixel region PX3, and the fourth pixel region PX4. Thereby, the first connection pattern 152 may be easily connected to the plurality of ground regions 120g (e.g., four ground regions 120g) disposed in the first pixel region PX1, the second pixel region PX2, the third pixel region PX3, and the fourth pixel region PX4.

In this instance, a partial portion of the first connection pattern 152 may be disposed on a partial portion of the first isolation portion 126a between the first pixel region PX1 and the third pixel region PX3, on a partial portion of the first isolation portion 126a between the second pixel region PX2 and the fourth pixel region PX4, on a partial portion of the second isolation portion 126b between the first pixel region PX1 and the second pixel region PX2, and on a partial portion of the second isolation portion 126b between the third pixel region PX3 and the fourth pixel region PX4.

While some example embodiments may include the ground region 120g in the semiconductor substrate 110a and the first connection pattern 152 connected to the ground region 120g, example embodiments are not limited thereto. In some embodiments, the ground region 120g might not be provided in the semiconductor substrate 110a, and the first connection pattern 152 may be connected to the semiconductor substrate 110a or the first conductivity type well 120b. Other various modifications are possible.

In an embodiment, the second connection pattern 154 may include a first connection portion 154a and a second connection portion 154b.

The first connection portion 154a may be disposed in the first pixel region PX1 and the third pixel region PX3 and be connected to the floating diffusion regions 120f included in the first pixel region PX1 and the third pixel region PX3.

For example, the first connection portion 154a may be disposed in a central portion of the first pixel region PX1 and the third pixel region PX3 adjacent to each other in the second direction (the Y-axis direction in the drawings). The floating diffusion region 120f may be disposed in a portion of the first active region 114a adjacent to the first connection portion 154a in each of the first pixel region PX1 and the third pixel region PX3. In an embodiment, a plurality of (e.g., two) floating diffusion regions 120f may be disposed in each pixel region PX, and the first connection portion 154a may be connected a plurality of (e.g., four) floating diffusion regions 120f included in the first and third pixel regions PX1 and PX3. Thereby, the first connection portion 154a may be easily connected to the floating diffusion regions 120f disposed in the first pixel region PX1 and the third pixel region PX3.

In this instance, a partial portion of the first connection portion 154a may be disposed on a partial portion of the first isolation portion 126a that is disposed between the first pixel region PX1 and the third pixel region PX3.

The second connection portion 154b may be disposed in the second pixel region PX2 and the fourth pixel region PX4 and be connected to the floating diffusion regions 120f included in the second pixel region PX2 and the fourth pixel region PX4.

For example, the second connection portion 154b may be disposed in a central portion of the second pixel region PX2 and the fourth pixel region PX4 adjacent to each other in the second direction (the Y-axis direction in the drawings). The floating diffusion region 120f may be disposed in a portion of the first active region 114a adjacent to the second connection portion 154b in each of the second pixel region PX2 and the fourth pixel region PX4. In an embodiment, a plurality of (e.g., two) floating diffusion regions 120f may be disposed in each pixel region PX, and the second connection portion 154b may be connected a plurality of (e.g., four) floating diffusion regions 120f included in the second and fourth pixel regions PX2 and PX4. Thereby, the second connection portion 154b may be easily connected to the floating diffusion regions 120f disposed in the second pixel region PX2 and the fourth pixel region PX4.

In this instance, a partial portion of the second connection portion 154b may be disposed on a partial portion of the first isolation portion 126a that is disposed between the second pixel region PX2 and the fourth pixel region PX4.

In the four pixel regions PX that constitute one unit pixel group, one first connection pattern 152 may be disposed between the first connection portion 154a and the second connection portion 154b in the first direction (the X-axis direction in the drawings).

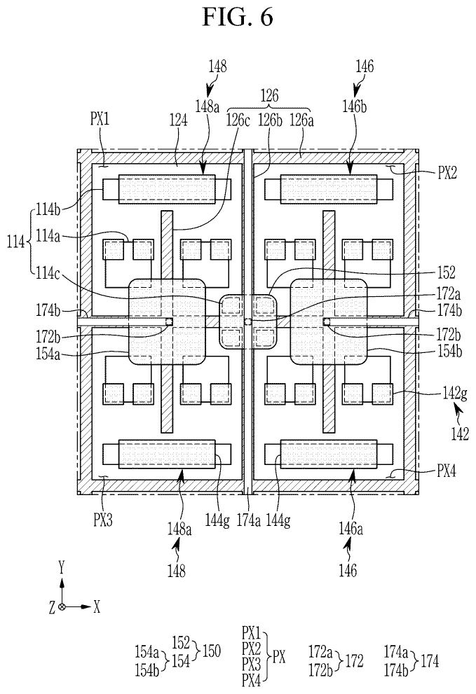

Since the first connection pattern 152 and/or the second connection pattern 154 may be shared in at least two pixel regions PX, a structure of the connection pattern 150 and a structure of the wiring portion 170 may be simplified. For example, a number of the first contact vias 172 may be reduced and an interval between the first contact vias 172 may increase. This will be described in more detail later in the description of the first contact via 172 with reference to FIG. 6.

In an embodiment, the connection pattern 150 may include a doped region DR that includes a dopant, and may further include a undoped region UR. The doped region DR may be adjacent to a first surface (e.g., an outer surface) of the connection pattern 150 that is adjacent to the first surface 111 of the substrate 110. The undoped region UR may be adjacent to a second surface (e.g., an inner surface) of the connection pattern 150 that is opposite to the first surface of the connection pattern 150.

For example, the first connection pattern 152 may include a first doped region DR1 that includes a first conductive type dopant, and may further include a first undoped region UR1 or a lightly doped region. The first doped region DR1 may be adjacent to a first surface of the first connection pattern 152. The first undoped region UR1 or the lightly doped region may be adjacent to a second surface of the first connection pattern 152. An electrical resistance may be reduced by the first doped region DR1, and a leakage current may be reduced and unwanted signal generation or so on may be limited and/or prevented by the first undoped region UR1.

For example, a depth of the first doped region DR1 may be the same as or smaller than a depth of the first undoped region UR1. The depth may refer to a depth in a thickness direction of the substrate 110, for example, a maximum depth. Thereby, the first undoped region UR1 may be sufficiently secured and the leakage current may be effectively reduced and the unwanted signal generation or so on may be effectively limited and/or prevented by the first undoped region UR1. In some embodiments, a depth of the first doped region DR1 may be greater than a depth of the first undoped region UR1. Thereby, the electrical resistance may be effectively reduced. In some embodiments, a ratio of a depth of the first doped region DR1 to an entire depth of the first connection pattern 152 may be 30% to 70% (e.g., 40% to 60%), but example embodiments are not limited thereto. In some embodiments, the first undoped region UR1 may be omitted.

For example, the second connection pattern 154 may include a second doped region DR2 that includes a second conductive type dopant, and may further include a second undoped region UR2 or a lightly doped region. The second doped region DR2 may be adjacent to a first surface of the second connection pattern 154. The second undoped region UR2 or the lightly doped region may be adjacent to a second surface of the second connection pattern 154. An electrical resistance may be reduced by the second doped region DR2, and a leakage current may be reduced and unwanted signal generation or so on may be limited and/or prevented by the second undoped region UR2.

For example, a depth of the second doped region DR2 may be the same as or smaller than a depth of the second undoped region UR2. Thereby, the second undoped region UR2 may be sufficiently secured and the leakage current may be effectively reduced and the unwanted signal generation or so on may be effectively limited and/or prevented by the second undoped region UR2. In some embodiments, a depth of the second doped region DR2 may be greater than a depth of the second undoped region UR2. Thereby, the electrical resistance may be effectively reduced. In some embodiments, a ratio of a depth of the second doped region DR2 to an entire depth of the second connection pattern 154 may be 30% to 70% (e.g., 40% to 60%), but example embodiments are not limited thereto. In some embodiments, the second undoped region UR2 may be omitted.

In an embodiment, the first gate electrode 142g, the second gate electrode 144g, and/or the connection pattern 150 (e.g., the first connection pattern 152 and/or the second connection pattern 154) may be the buried pattern 132 that has a buried structure buried in the substrate 110. That is, the plurality of buried patterns 132 may include the first gate electrode 142g, the second gate electrode 144g, and/or the connection pattern 150 (e.g., the first connection pattern 152 and/or the second connection pattern 154). For example, the first transistor 142, the second transistor 144, the third transistor 146, the fourth transistor 148, the reset transistor 146a, the selection transistor 146b, and/or the source follower transistor 148a may be referred to as a buried transistor, the first gate electrode 142g and/or the second gate electrode 144g may be referred to as a buried gate electrode, and the connection pattern 150 may be referred to as a buried connection pattern or a buried local interconnector.

The buried structure buried in the substrate 110 may refer to a structure that includes a portion disposed between the first surface 111 and the second surface 112 of the substrate 110 and/or a portion the same as the first surface 111 of the substrate 110, and not includes a portion outside the first surface 111 of the substrate 110 or a portion protruding from the first surface 111 of the substrate 110 to the wiring portion 170.

In an embodiment, the plurality of transistors 140 may have the buried structure and may be formed by an easy process. For example, a capping layer, a space, or so on included in a transistor according to a comparative example may be omitted. The plurality of buried patterns 132 might not include a portion that is disposed on the first surface 111 of the substrate 110, and a thickness of the first interlayer insulation layer 172i may be reduced. That is, in the comparative example where at least a partial portion of a plurality of transistors and/or a connection pattern is disposed on a first surface of a substrate, a first interlayer insulation layer may have a relatively large thickness to electrically insulate the plurality of transistors and a first wiring layer. On the other hand, in an embodiment, the plurality of transistors 140 and/or the connection pattern 150 might not be disposed on the first surface 111 of the substrate 110, and the thickness of the first interlayer insulation layer 172i that is disposed on the first surface 111 of the substrate 110 may be reduced. Thereby, a depth of the first contact via 172 may be reduced and thus an electrical resistance due to the first contact via 172 may be reduced.

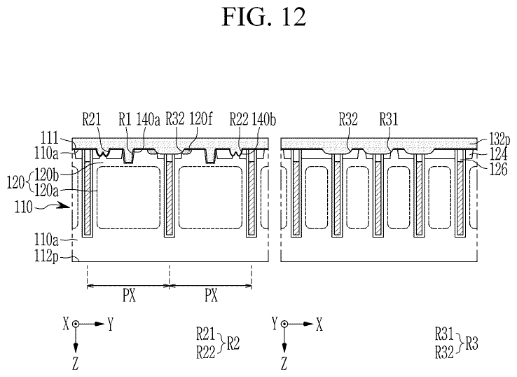

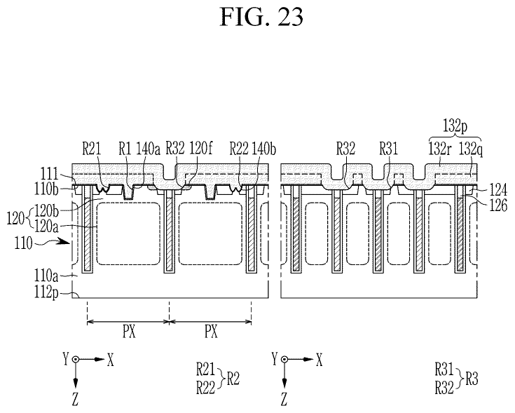

In an embodiment, the plurality of buried patterns 132, each having the buried structure, may be formed by the same process. The phrase that the plurality of buried patterns 132 are formed by the same process may mean that the plurality of buried patterns 132 are formed by forming a buried layer 132p (refer to FIG. 12 or FIG. 23) including portions filled inside a plurality of recesses in the substrate 110 and a portion disposed on the surface insulation layer 110b and then performing a removal process of the portion of the buried layer 132p on the surface insulation layer 110b. For example, when final structures of the plurality of buried patterns 132 may have the buried structures by the same removal process, for example, the same chemical mechanical polishing (CMP) process, the plurality of buried patterns 132 may be regarded as being formed by the same process. For example, the final structures of the plurality of buried patterns 132 may have the buried structure by one chemical mechanical polishing (CMP) process that is performed to the first surface 111 of the substrate 110.

In an embodiment, the plurality of buried patterns 132 may include the same base material. The base material may refer to a material of the largest amount. That is, including the same base material may include an embodiment where the same material is included, an embodiment where the same material is included but there is a difference in composition, and an embodiment where there is a difference in presence or absence of doping, conductivity type, doping concentration, dopant material, or so on. For example, when the plurality of buried patterns 132 includes the same semiconductor material and there is a difference in presence or absence of doping, conductivity type, doping concentration, dopant material, or so on, the plurality of buried patterns 132 may be regarded to include the same base material.

In an embodiment, the plurality of buried patterns 132, for example, the first gate electrode 142g, the second gate electrode 144g, the first connection pattern 152, and/or the second connection pattern 154 may include the same base material (e.g., the same semiconductor material). For example, the plurality of buried patterns 132, for example, the first gate electrode 142g, the second gate electrode 144g, the first connection pattern 152, and/or the second connection pattern 154 may include polycrystalline semiconductor (e.g., polycrystalline silicon). The plurality of buried patterns 132 may be referred to as buried semiconductor patterns.

When the plurality of buried patterns 132 include the semiconductor material, the plurality of buried patterns 132 may be easily formed and may have a desired conductivity and/or electrical conductivity depending on the presence or absence of doping and/or the doping concentration. However, example embodiments are not limited thereto. In some embodiments, the plurality of buried patterns 132 may include a material other than the semiconductor material as the base material.

In an embodiment, a plurality of first surfaces (e.g., a plurality of outer surfaces) of the plurality of buried patterns 132 that are adjacent to the first surface 111 of the substrate 110 may include concave portions S1, S2, S3, and S4, respectively. The concave portion S1, S2, S3, or S4 may have a concave shape so that the buried pattern 132 includes a portion disposed between the first surface 111 of the substrate 110 and the second surface 112 of the substrate 110. For example, a surface (e.g. an outer surface) of the first gate electrode 142g may have a first concave portion S1, a surface (e.g. an outer surface) of the second gate electrode 144g may have a second concave portion S2, a surface (e.g. an outer surface) of the first connection pattern 152 may have a third concave portion S3, and/or the second connection pattern 154 may have a fourth concave portion S4. The concave portion S1, S2, S3, or S4 may be a portion formed due to dishing in the chemical mechanical polishing process.

In an embodiment, the plurality of first surfaces (e.g., the plurality of outer surfaces) of the plurality of buried patterns 132 that are adjacent to the first surface 111 of the substrate 110 may have the same surface property. For example, the surface of the first gate electrode 142g, the surface of the second gate electrode 144g, the surface of the first connection pattern 152, and/or the surface of the second connection pattern 154 may have the same surface property. Having the same surface property may refer to have a property regarded to be formed by the same process (e.g., a chemical mechanical polishing process), to have the same or similar trace (e.g., a polishing mark), or to have a surface roughness within a margin of error (e.g., within 10%).

In an embodiment, each of the plurality of buried patterns 132 may include a corner portion that has a rounded portion RP. That is, surface topology between the buried pattern 132 and the substrate 110 may be the same in the plurality of buried patterns 132. For example, a corner portion of the first gate electrode 142g, a corner portion of the second gate electrode 144g, a corner portion of the first connection pattern 152, and/or a corner portion of the second connection pattern 154 may include the rounded portion RP of the same or similar shape. The rounded portion may refer to a portion that is adjacent to the first surface 111 of the substrate 110 at a side surface of the buried pattern 132 that is adjacent to the substrate 110. This may be because the plurality of buried patterns 132 may be formed by forming the plurality of recesses in the substrate 110 by the same or similar etching process and then removing the partial portion of the buried layer 132p by the same removal process.

In an embodiment, in the plurality of buried patterns 132, there may be a difference in presence or absence of a gate insulation layer or thickness of the gate insulation layer. When the plurality of buried patterns 132 that perform different operations or actions have the same buried structure, the presence or the thickness of the gate insulation layer may be different in consideration of properties of the plurality of buried patterns 132. For example, a thickness of the first gate insulation layer 140a included in the first transistor 142 or the third transistor 146 may be greater than a thickness of the second gate insulation layer 140b included in the fourth transistor 148, and the connection pattern 150 might not include a gate insulation layer (e.g., the first or second gate insulation layer 140a or 140b) for an ohmic contact. Accordingly, the plurality of buried patterns 132 may have three or more structures that have the difference in presence or absence of the gate insulation layer or thickness of the gate insulation layer. A manufacturing method of the plurality of buried patterns 132 will be described in more detail in a manufacturing method of the image sensor 10.

In the drawings and the descriptions, a structure or an arrangement of the pixel circuit 130 is illustrated or described as an example, and example embodiments are not limited thereto. Accordingly, the pixel circuit 130 may have any of various structures or arrangements.

In an embodiment, by the connection pattern 150, the number of the first contact vias 172 may be reduced and the interval between the first contact vias 172 may increase. This will be described in detail with reference to FIG. 6 together with FIG. 2 and FIG. 3.

FIG. 6 is a plan view that schematically illustrates a partial portion of the photoelectric conversion substrate 100 included in the image sensor 10 illustrated in FIG. 2. In FIG. 6, a part of the first contact vias 172 and the first wiring layer 174 that are electrically connected to the connection pattern 150 are additionally illustrated in a portion corresponding to FIG. 3. For a clearer understanding and simpler illustration, in FIG. 6, the second conductivity type well 120a is omitted, and the first contact via 172 and the first wiring layer 174 that are electrically connected to a portion (e.g., the plurality of transistors 140) other than the connection pattern 150 are omitted.

Referring to FIG. 2, FIG. 3, and FIG. 6, in an embodiment, the first contact via 172 may include a contact via for a connection pattern that is connected to the connection pattern 150. For example, the contact via for the connection pattern may include a first via 172a (e.g., a contact via for ground) that is connected to the first connection pattern 152 and a second via 172a (e.g., a contact via for floating diffusion) that is connected to the second connection pattern 154. The first wiring layer 174 may include a first wiring portion 174a that is electrically connected to the first via 172a and a second wiring portion 174b that is electrically connected to the second via 172b.

In an embodiment, the first connection pattern 152 or the second connection pattern 154 are disposed in at least two pixel regions PX, and a number of the first vias 172a or the second via 172b that is connected to the first connection pattern 152 or the second connection pattern 154 may be reduced.

For example, in four pixel regions PX that constitute one unit pixel group, two first vias 172a that are connected to the first connection portion 154a and the second connection portion 154b of the first connection pattern 152, respectively, and one second via 172 that is connected to one second connection pattern 154 may be included. For reference, in a comparative example, two floating diffusion regions and one ground region are included in one pixel region, first vias are connected to the floating diffusion regions, respectively, and second vias are connected to the ground regions, respectively. Accordingly, eight first vias and four second vias are included in four pixel regions PX that constitute one unit pixel group.

Thereby, the number of the first vias 172a and second via 172b (i.e., a number of the first contact vias 172) that are connected to the first connection pattern 152 and the second connection pattern 154 may be reduced. Accordingly, it may be suitable to reduce a size of pixels, and problems that may be induced by the interval reduction between the first contact vias 172 may be effectively limited and/or prevented. An interval between the first via 172a and the second via 172b (i.e., the interval between the first contact vias 172) may increase, and an area (e.g., a planar area) of the first wiring layer 174 that is connected to the first contact via 172 may be reduced. Accordingly, a parasitic capacitance between the floating diffusion region 120f and the first wiring layer 174 may be reduced. Further, an interval between a plurality of portions of the first wiring layer 174 that are connected to the first contact vias 172 may increase and thus a parasitic capacitance between the plurality of first contact vias 172 or a parasitic capacitance between the plurality of portions of the first wiring layer 174 may be reduced.

In a plan view, the first via 172a may be disposed in a central portion of the first connection pattern 152. For example, in a plan view, one first via 172 may be disposed in the central portion of one unit pixel group where the first pixel region PX1, the second pixel region PX2, the third pixel region PX3, and the fourth pixel region PX4 are adjacent to each other. In a plan view, the first via 172a may overlap an intersection portion of the first isolation portion 126a and the second the isolation portion 126b where the first pixel region PX1, the second pixel region PX2, the third pixel region PX3, and the fourth pixel region PX4 are adjacent to each other.

As such, the first via 172a may be disposed in the first connection pattern 152 or the central portion of one unit pixel group, and an electrical transfer path may be effectively reduced.

In a plan view, the second via 172b may be disposed in a central portion of the second connection pattern 154. That is, the second via 172b may be disposed in a central portion of the first connection portion 154a in the first pixel region PX1 and the third pixel region PX3, and the second via 172b may be disposed in a central portion of the second connection portion 154b in the second pixel region PX2 and the fourth pixel region PX4. In a plan view, one second via 172b may overlap a partial portion (e.g., a central portion) of the first isolation portion 126a between the first pixel region PX1 and the third pixel region PX3, and another second via 172b may overlap a partial portion (e.g., a central portion) of the first isolation portion 126a between the second pixel region PX2 and the fourth pixel region PX4.

When the second via 172b may be disposed in the second connection pattern 154 or central portions of two pixel regions PX that are adjacent to each other in the second direction (the Y-axis direction in the drawings), and an electrical transfer path may be effectively reduced.

In FIG. 6, an example is illustrated where the first wiring portion 174a electrically connected to the first via 172a extends in the second direction (the Y-axis direction in the drawings) on the second isolation portion 126b, and the second wiring portion 174b electrically connected to the second via 172b extends in the first direction (the X-axis direction in the drawings) on the first isolation portion 126a. The first wiring portion 174a and/or the second wiring portion 174b may be disposed on the isolation portion 126 and thus a parasitic capacitance may be reduced.

However, example embodiments are not limited thereto. A position, an arrangement, or so on of the first via 172a and/or the second via 172b, the first wiring portion 174a and/or the second wiring portion 174b in a plan view may be variously modified.

In an embodiment, a front end of line (FEOL) that includes the first transistor 142, the second transistor 144, the connection pattern 150, and the first contact via 172 connected thereto may be disposed on the substrate 110. That is, all elements or devices configured to operate the image sensor 10 may be included in the photoelectric conversion substrate 100. For example, the image sensor 10 may have a two-layered stacking structure including the photoelectric conversion substrate 100 and the additional wiring portion 200.

Accordingly, by forming the plurality of transistors 140 at the substrate 110, an additional substrate (e.g., a middle substrate between the wiring portion 170 on the substrate 110 and the additional wiring portion 200) for at least a part of the plurality of transistors 140 is not needed. Therefore, a number of processes may be reduced and manufacturing cost may be reduced. For reference, in a comparative example in which a first transistor is formed at a substrate and a second transistor is formed at an additional substrate (e.g., a middle substrate) between a wiring portion on the substrate and an additional wiring portion, a process is complicated and manufacturing cost is high.

It is described as an example that the image sensor 10 has the two-layered stacking structure, but example embodiments are not limited thereto. In some embodiments, the wiring portion 170 that is disposed on the substrate 110 may include a member or an element included in the additional wiring portion 200, and the image sensor 10 include a single portion. In some embodiments, the image sensor 10 may have a stacking structure of three or more layers. A substrate between the wiring portion 170 on the substrate 110 and the additional wiring portion 200 may include a DRAM, an additional element configured to perform a global shutter or a rolling shutter, or so on. In this instance, the wiring portion 170 on the substrate 110 may include the plurality of transistors 140 (e.g., the first transistor 142 and the second transistor 144).

According to an embodiment, the first transistor 142, the second transistor 144, and/or the connection pattern 150 having different structures may be included together at the substrate 110, and a number of processes may be reduced and manufacturing cost may be reduced. Each of the first transistor 142, the second transistor 144, and/or the connection pattern 150 may have the buried structure and thus the pixel circuit 130 may be formed by an easy process and an electrical resistance may be reduced by reducing the depth of the first contact via 172. The connection pattern 150 may be shared in the plurality of pixel regions PX and thus the number of the first contact vias 172 and the area of the first wiring layer 174 may be reduced and the interval between the first contact vias 172 may increase, thereby reducing the parasitic capacitance. By reducing the parasitic capacitance, conversion gain may be improved. Accordingly, efficiency and productivity of the image sensor 10 may be improved and/or enhanced.

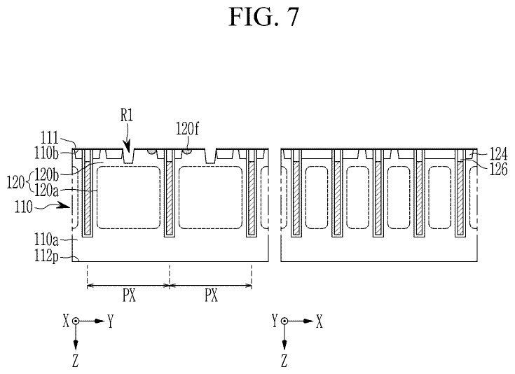

Manufacturing methods of an image sensor 10 will be described in detail with reference to FIG. 7 to FIG. 24. To the extent that an element is not described in detail below, it may be understood that the element is at least substantially similar (and/or the same as) to a corresponding element that has been described elsewhere within the present disclosure. A portion which is not described in the above will be described in detail.

FIG. 7 to FIG. 18 are cross-sectional views that schematically illustrate a manufacturing method of an image sensor 10 according to an embodiment. FIG. 7 to FIG. 18 illustrate a portion corresponding to FIG. 2.

As illustrated in FIG. 7, a device isolation portion 124, an isolation portion 126, a photoelectric conversion portion 120, and a first recess R1 may be formed at a substrate 110. The substrate 110 may include a semiconductor substrate 110a and a surface insulation layer 110b, and may have a first surface 111 and a preliminary surface 112p.

For example, the device isolation portion 124 and the isolation portion 126 may be formed on the semiconductor substrate 110a.

A mask pattern may be formed on a first surface of the semiconductor substrate 110a adjacent to the first surface 111 of the substrate 110. The mask pattern may have an opening that exposes a region corresponding to the device isolation portion 124. A shallow trench may be formed by etching a part of the substrate 110 that is exposed through the opening of the mask pattern. The device isolation portion 124 may be formed on a portion adjacent to the first surface of the semiconductor substrate 110a by filling an insulating material layer in the shallow trench. A mask pattern may be formed on the first surface of the semiconductor substrate 110a. The mask pattern may have an opening that exposes a region corresponding to the isolation portion 126. A deep trench may be formed by etching a part of the substrate 110 that is exposed through the opening of the mask pattern. The isolation portion 126 may be formed on a portion adjacent to the first surface of the semiconductor substrate 110a by filling an insulating material layer and/or a conductive layer in the deep trench. In some embodiments, between the process of forming the deep trench and the process of forming the isolation portion 126, a side wall doping region may be further formed at a periphery of the isolation portion 126 by doping a dopant at a periphery of the deep trench.

In an embodiment, the device isolation portion 124 and/or the isolation portion 126 may be formed by any of various processes, and the device isolation portion 124 and/or the isolation portion 126 may include or be formed of any of various materials.

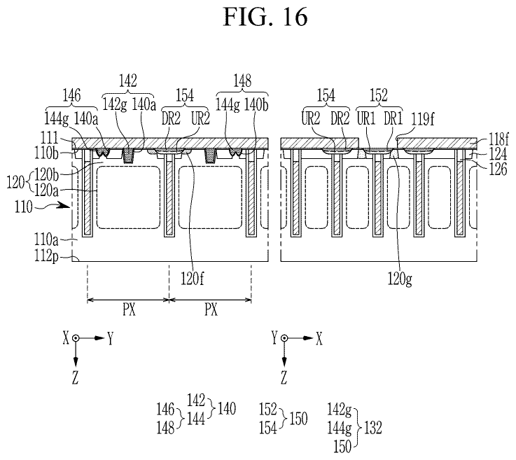

For example, by doping a dopant to a partial region of the semiconductor substrate 110a in a doping process, a first conductivity type well 120b, a second conductivity type well 120a, and/or a floating diffusion region 120f may be formed. The doping process may be performed by any of various processes (e.g., an ion implantation process or so on). In some embodiments, the first conductivity type well 120b and/or the floating diffusion region 120f might not be formed in the doping process, or the first conductivity type well 120b and/or the floating diffusion region 120f may be formed in a subsequent process. In some embodiments, the doping process may include a process of forming a ground region 120g (refer to FIG. 16) or so on. Other various modifications are possible.

For example, the surface insulation layer 110b may be formed on the first surface of the semiconductor substrate 110a. The surface insulation layer 110b may be formed by any of various processes (e.g., a deposition process).

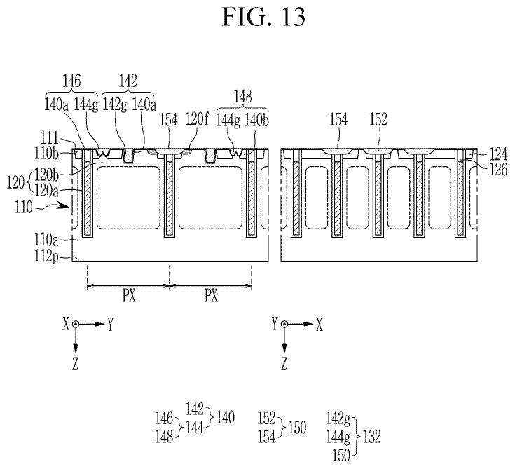

For example, the first recess R1 may be formed by performing an etching process at a side of the first surface 111 of the substrate 110. The first recess R1 may be a recess for a first transistor 142 (refer to FIG. 13).

More particularly, a first mask layer having a first opening may be formed on the first surface 111 of the substrate 110. The first opening of the first mask layer may expose a portion of the substrate 110 where the first transistor 142 will be formed. The first recess R1 may be formed by removing a partial portion of the substrate 110 using the first mask layer at the side of the first surface 111 of the substrate 110. After forming the first recess R1, the first mask layer may be removed.

The first mask layer may include or be formed of any of various materials (e.g., a photosensitive material). A patterning process of forming the first opening at the first mask layer may be performed by any of various processes (e.g., a photolithography process). The process of removing the partial portion of the substrate 110 using the first opening of the first mask layer may be performed by an etching process (e.g., a dry etching process). In the etching process of forming the first recess R1, an etching material capable of etching the substrate 110 may be used. The process of removing the first mask layer may be performed by any of various etching processes (e.g., a dry etching process and/or a wet etching process).

In an embodiment, a process order of the device isolation portion 124, the isolation portion 126, the first conductivity type well 120b, the second conductivity type well 120a, the floating diffusion region 120f, the surface insulation layer 110b, and/or the first recess R1 may be variously modified. For example, at least one of the process of forming the first mask layer, the process of forming the first recess R1, or the process of removing the first mask layer may be performed before the doping process of forming the first conductivity type well 120b, the second conductivity type well 120a, and/or the floating diffusion region 120f, or after the doping process of forming the first conductivity type well 120b, the second conductivity type well 120a, and/or the floating diffusion region 120f.

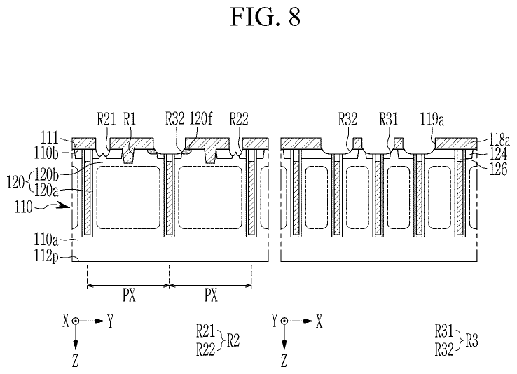

As illustrated in FIG. 8, a second recess R2 and a third recess R3 may be formed by performing an etching process at a side of the first surface 111 of the substrate 110. The second recess R2 may be a recess portion for a second transistor 144 (refer to FIG. 13), and the third recess R3 may be a recess portion for a connection pattern 150 (refer to FIG. 13). The second recess R2 may include a first recess portion R21 for a third transistor 146 (refer to FIG. 13) and a second recess portion R22 for a fourth transistor 148 (refer to FIG. 13). The third recess R3 may include a first connection recess R31 for a first connection pattern 152 (refer to FIG. 13) that will be connected to the ground region 120g and a second connection recess R32 for a second connection pattern 154 (refer to FIG. 13) that will be connected to the floating diffusion region 120f.

For example, the second recess R2 and the third recess R3 may be formed by performing an etching process at the side of the first surface 111 of the substrate 110. More particularly, a second mask layer 118a having a second opening 119a may be formed on the first surface 111 of the substrate 110. The second opening 119a of the second mask layer 118a may expose portions of the substrate 110 where the second transistor 144 and the connection pattern 150 will be formed. The second recess R2 and the third recess R3 may be formed by removing partial portions of the substrate 110 exposed by the second opening 119a at the side of the first surface 111 of the substrate 110. After forming the second recess R2 and the third recess R3, the second mask layer 118a may be removed.

The second mask layer 118a may include or be formed of any of various materials (e.g., a photosensitive material). A patterning process of forming the second opening 119a at the first mask layer 118a may be performed by any of various processes (e.g., a photolithography process). The process of removing the partial portions of the substrate 110 using the second opening 119a of the second mask layer 118a may be performed by an etching process (e.g., a dry etching process). In the etching process of the second recess R2 and the third recess R3, an etching material capable of etching the isolation portion 126 and/or the device isolation portion 124 may be used. The process of removing the second mask layer 118a may be performed by any of various etching processes (e.g., a dry etching process and/or a wet etching process). However, example embodiments are not limited thereto, and various modifications are possible.

In an embodiment, the second recess R2 may be disposed between two device isolation portions 124 that are adjacent to each other. The etching material used for forming the second recess R2 may be a material that is capable of easily etching the device isolation portion 124 (e.g., an insulation layer) and does not etch the substrate 110 or etches the substrate 110 less than the device isolation portion 124. Thereby, each of partial portions of two device isolation portions 124 at both sides may be easily etched to form a convex portion having a relatively large depth, and a portion of the substrate 110 between two device isolation portions 124 might not be etched or may be etched less than two device isolation portions 124 to have a concave portion having a relatively small depth. Accordingly, the second recess R2 of a three dimensional structure that has the concave portion in a central portion and convex portions between the central portion and both side portions may be easily formed.

The third recess R3 may be disposed to include a portion where the isolation portion 126 and/or the device isolation portion 124 is disposed to have a desirable shape. For example, at least a central portion of the third recess R3 may be disposed on the isolation portion 126 and/or the device isolation portion 124, and thus, the third recess R3 of the desirable shape may be easily formed at a desirable position by the etching material capable of etching the isolation portion 126 and/or the device isolation portion 124.

Subsequently, a channel portion of a third transistor 146 (e.g., channel portions of a reset transistor 146a and a selection transistor 146b) may be formed by performing a doping process.

More particularly, a third mask layer having a third opening may be formed on the first surface 111 of the substrate 110. The third opening of the third mask layer may expose a portion of the substrate 110 where the third transistor 146 will be formed. The channel portion of the third transistor 146 may be formed by doping a dopant to a partial portion of the substrate 110 exposed by the third opening. After forming the channel portion, the third mask layer may be removed.

The third mask layer may include or be formed of any of various materials (e.g., a photosensitive material). A patterning process of forming the third opening at the third mask layer may be performed by any of various processes (e.g., a photolithography process). The doping process may be performed by any of various processes (e.g., an ion implantation process or so on). The process of removing the third mask layer may be performed by any of various etching processes (e.g., a dry etching process and/or a wet etching process). However, example embodiments are not limited thereto, and various modifications are possible.

As described, in some embodiments, the doping process of forming the channel portion of the third transistor 146 is performed and a channel portion of the fourth transistor 148 is not formed, but example embodiments are not limited thereto. The channel portion of the fourth transistor 148 may be formed in the doping process of forming the channel portion of the third transistor 146, or a doping process of forming the channel portion of the fourth transistor 148 may be separately performed from the doping process of forming the channel portion of the third transistor 146. In some embodiments, the doping process of forming the channel portion of the third transistor 146 may be omitted.

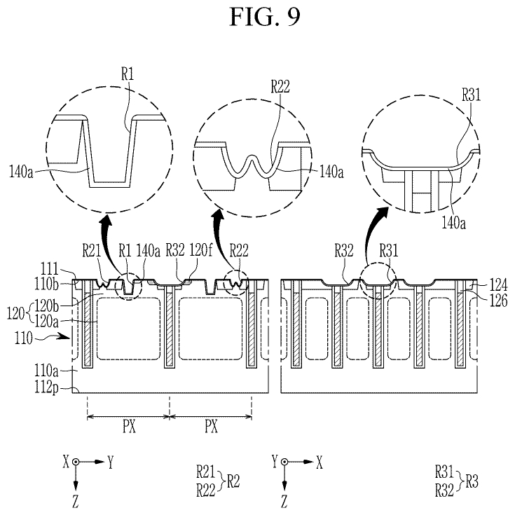

Subsequently, as illustrated in FIG. 9 to FIG. 11, a first gate insulation layer 140a or a second gate insulation layer 140b may be formed in the first recess R1 and the second recess R2. For an ohmic contact of the connection pattern 150, the first gate insulation layer 140a and the second gate insulation layer 140b might not be disposed in the third recess R3 where the connection pattern 150 will be disposed.

More particularly, as illustrated in FIG. 9, the first gate insulation layer 140a may be formed. The first gate insulation layer 140a may have a thickness suitable to the first transistor 142 and the third transistor 146.

The first gate insulation layer 140a may include or be formed of at least one of oxide, nitride, oxynitride, a high dielectric constant material that has a dielectric constant higher than a dielectric constant of silicon oxide, or a low dielectric constant material that has a dielectric constant lower than a dielectric constant of silicon oxide. For example, the first gate insulation layer 140a may include or be formed of at least one of silicon oxide, silicon nitride, silicon oxynitride, hafnium oxide, aluminum oxide, or tantalum oxide. The first gate insulation layer 140a may include or be formed of one insulation layer, or include a plurality of insulation layers.

For example, the first gate insulation layer 140a may be formed using a thermal oxidation process or so on. Thereby, the first gate insulation layer 140a may be partially formed on an exposed portion of the substrate 110 where the surface insulation layer 110b is not disposed. In this instance, the first gate insulation layer 140a may include or be formed of silicon oxide. However, example embodiments are not limited thereto. The first gate insulation layer 140a may be formed by any of various processes.

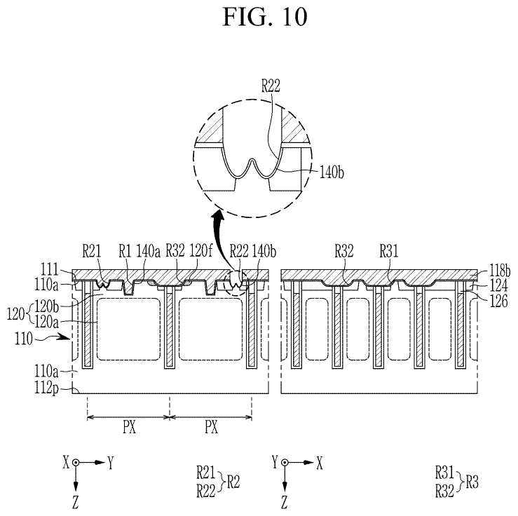

As illustrated in FIG. 10, in the second recess portion R22 in which the fourth transistor 148 will be formed, the first gate insulation layer 140a may be removed and the second gate insulation layer 140b may be formed.

The second gate insulation layer 140b may include or be formed of at least one of oxide, nitride, oxynitride, a high dielectric constant material that has a dielectric constant higher than a dielectric constant of silicon oxide, or a low dielectric constant material that has a dielectric constant lower than a dielectric constant of silicon oxide. For example, the second gate insulation layer 140b may include or be formed of at least one of silicon oxide, silicon nitride, silicon oxynitride, hafnium oxide, aluminum oxide, or tantalum oxide. The second gate insulation layer 140b may include or be formed of one insulation layer, or include a plurality of insulation layers.

For example, a fourth mask layer 118b having a fourth opening 119b may be formed on the first surface 111 of the substrate 110. The fourth opening 119b of the fourth mask layer 118b may expose a portion of the substrate 110 where the second transistor 148 will be formed. The first gate insulation layer 140a may be removed in the second recess portion R22 exposed by the fourth opening 119b, and the second gate insulation layer 140b may be formed in the second recess portion R22. After forming the second gate insulation layer 140b, the fourth mask layer 118b may be removed.

The fourth mask layer 118b may include or be formed of any of various materials (e.g., a photosensitive material). A patterning process of forming the fourth opening 119b at the fourth mask layer 118b may be performed by any of various processes (e.g., a photolithography process). The process of removing the partial portion of the first gate insulation layer 140a exposed by the fourth opening 119b may be performed by an etching process (e.g., a wet etching process). For example, the second gate insulation layer 140b may be formed using a thermal oxidation process or so on. Thereby, the second gate insulation layer 140b may be partially formed on a portion of the substrate 110 exposed by the fourth opening 119b. In this instance, the second gate insulation layer 140b may include or be formed of silicon oxide. However, example embodiments are not limited thereto. The first gate insulation layer 140a may be formed by any of various processes. The process of removing the fourth mask layer 118b may be performed by any of various etching processes (e.g., a dry etching process and/or a wet etching process). For example, the process of removing the fourth mask layer 118b may be performed by a wet etching process. However, example embodiments are not limited thereto, and various modifications are possible.

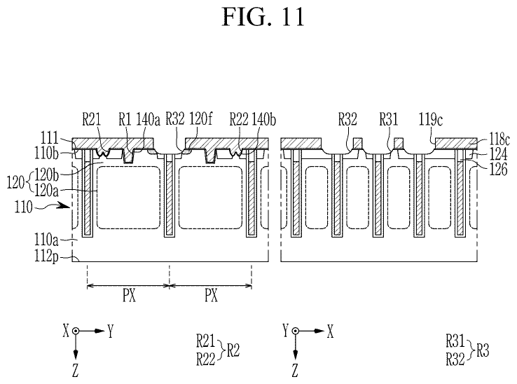

As illustrated in FIG. 11, the first gate insulation layer 140a may be removed in the third recess R3 where the connection pattern 150 will be formed.

For example, a fifth mask layer 118c having a fifth opening 119c may be formed on the first surface 111 of the substrate 110. The fifth opening 119c of the fifth mask layer 118c may expose a portion of the substrate 110 where the connection pattern 150 will be formed. The first gate insulation layer 140a may be removed in the third recess R3 exposed by the fifth opening 119c. After forming the first gate insulation layer 140a in the third recess R3, the fifth mask layer 118c may be removed.

The fifth mask layer 118c may include or be formed of any of various materials (e.g., a photosensitive material). A patterning process of forming the fifth opening 119c at the fifth mask layer 118c may be performed by any of various processes (e.g., a photolithography process). The process of removing the partial portion of the first gate insulation layer 140a exposed by the fifth opening 119c may be performed by an etching process (e.g., a wet etching process). The process of removing the fifth mask layer 118c may be performed by any of various etching processes (e.g., a dry etching process and/or a wet etching process). However, example embodiments are not limited thereto, and various modifications are possible.

Subsequently, as illustrated in FIG. 12, a buried layer 132p may be formed on the first surface 111 of the substrate 110. The buried layer 132p may be formed on the first surface 111 of the substrate 110 to fill the first recess R1, the second recess R2, and the third recess R3.

The buried layer 132p may include or be formed of a conductive material or a semiconductor material as a base material that constitutes a buried pattern 132 (refer to FIG. 13) having a buried structure. For example, the buried layer 132p may include or be formed of an undoped semiconductor material (e.g., undoped polycrystalline semiconductor, as an example, undoped polycrystalline silicon). The buried layer 132p may be formed by any of various processes (e.g., a deposition process).

Subsequently, as illustrated in FIG. 13, a portion of the buried layer 132p (refer to FIG. 12) on the first surface 111 of the substrate 110 may be removed to form a buried pattern 132. For example, a chemical mechanical polishing process may be performed at a side of the first surface 111 of the substrate 110 to from buried patterns 132 in the first recess R1 (refer to FIG. 12), the second recess R2 (refer to FIG. 12), and the third recess R3 (refer to FIG. 12).

The buried pattern 132 configured to constitute a first gate electrode 142g of the first transistor 142 may be formed in the first recess R1, the buried pattern 132 configured to constitute a second gate electrode 144g of the second transistor 144 may be formed in the second recess R2, and the buried pattern 132 configured to constitute the connection pattern 150 may be formed in the third recess R3. More particularly, the buried pattern 132 on the first gate insulation layer 140a in the first recess portion R21 may constitute the second gate electrode 144g of the third transistor 146 (e.g., the selection transistor 146b and/or the reset transistor 146a). The buried pattern 132 on the second gate insulation layer 140b in the second recess portion R22 may constitute the second gate electrode 144g of the fourth transistor 148 (e.g., the source follower transistor 148a). The buried pattern 132 in the first connection recess R31 may constitute the first connection pattern 152, and the buried pattern 132 in the second connection recess R32 may constitute the second connection pattern 154.

Outer surfaces of the plurality of buried patterns 132 may include concave portions S1, S2, S3, and S4 (refer to FIG. 4 and FIG. 5), respectively, by dishing in a chemical mechanical polishing process. The plurality of surfaces of the plurality of buried patterns 132 may have the same surface property. Each of the plurality of buried patterns 132 may have a corner portion that has a rounded portion RP (refer to FIG. 4). Therefrom, it may be seen that the plurality of buried patterns 132 (e.g., the first gate electrode 142g, the second gate electrode 144g, the first connection pattern 152, and/or the second connection pattern 154) may be formed together by the same process (e.g., one chemical mechanical polishing process).

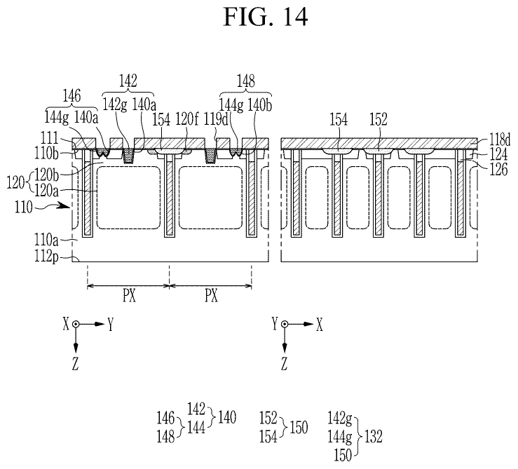

Subsequently, as illustrated in FIG. 14, a second conductivity type dopant may be doped into the plurality of transistors 140. Thereby, the second conductivity type dopant may be doped into the first and second gate electrodes 142g and 144g of the plurality of transistors 140, and/or the second conductivity type dopant may be doped into portions of an active region of the substrate 110 that are disposed at both sides of the second gate electrode 144g to form a source region and a drain region.

More particularly, a sixth mask layer 118d having a sixth opening 119d may be formed on the first surface 111 of the substrate 110. The sixth opening 119d of the sixth mask layer 118d may expose portions that include the first and second gate electrodes 142g and 144g of the plurality of transistors 140. The second conductivity type dopant may be doped into a portion exposed by the sixth opening 119d. After the doping process, the sixth mask layer 118d may be removed.

The sixth mask layer 118d may include or be formed of any of various materials (e.g., a photosensitive material). A patterning process of forming the sixth opening 119d at the sixth mask layer 118d may be performed by any of various processes (e.g., a photolithography process). The doping process may be performed by any of various processes (e.g., an ion implantation process or so on). The process of removing the sixth mask layer 118d may be performed by any of various etching processes (e.g., a dry etching process and/or a wet etching process). However, example embodiments are not limited thereto, and various modifications are possible.

In some embodiments, the source region and the drain region of the second transistor 144 are formed in the process of doping the second conductivity type dopant to the first and second gate electrodes 142g and 144g of the plurality of transistors 140, but example embodiments are not limited thereto. The source region and the drain region of the second transistor 144 may be formed by a process separate from the process of doping the second conductivity type dopant to the first and second gate electrodes 142g and 144g of the plurality of transistors 140. In some embodiments, the source region and the drain region of the second transistor 144 may be formed by a plurality of doping processes.

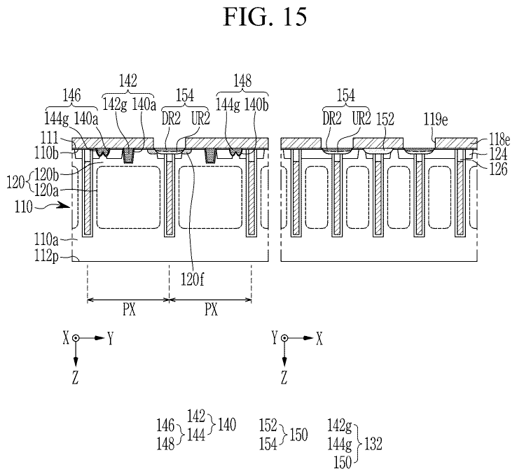

Subsequently, as illustrated in FIG. 15, a second conductivity type dopant may be doped into the second connection pattern 154.

More particularly, a seventh mask layer 118e having a seventh opening 119e may be formed on the first surface 111 of the substrate 110. The seventh opening 119e of the seventh mask layer 118e may expose the second connection pattern 154. The second conductivity type dopant may be doped into the second connection pattern 154 exposed by the seventh opening 119e. In an embodiment, in the process of doping the second conductivity type dopant to the second connection pattern 154, a second doped region DR2 may be formed at a portion of the second connection pattern 154 that is adjacent to the first surface 111 of the substrate 110, and a second undoped region UR2 may be disposed at a lower portion of the second doped region DR2. After the doping process, the seventh mask layer 118e may be removed.

The seventh mask layer 118e may include or be formed of any of various materials (e.g., a photosensitive material). A patterning process of forming the seventh opening 119e at the seventh mask layer 118e may be performed by any of various processes (e.g., a photolithography process). The doping process may be performed by any of various processes (e.g., an ion implantation process or so on). The process of removing the seventh mask layer 118e may be performed by any of various etching processes (e.g., a dry etching process and/or a wet etching process). However, example embodiments are not limited thereto, and various modifications are possible.

Subsequently, as illustrated in FIG. 16, a first conductivity type dopant may be doped into the first connection pattern 152. Further, the ground region 120g may be formed together at a side of the first surface 111 of the substrate 110.

More particularly, an eighth mask layer 118f having an eighth opening 119f may be formed on the first surface 111 of the substrate 110. The eighth opening 119f of the eighth mask layer 118f may expose the first connection pattern 152 and/or a portion of the substrate 110 that is adjacent to the first connection pattern 152. The first conductivity type dopant may be doped into the first connection pattern 152 exposed by the eighth opening 119f, and/or the first conductivity type dopant may be doped into the portion of the substrate 110 exposed by the eighth opening 119f to form the ground region 120g. In an embodiment, in the process of doping the first conductivity type dopant to the first connection pattern 152, a first doped region DR1 may be formed at a portion of the first connection pattern 152 that is adjacent to the first surface 111 of the substrate 110 and a second undoped region UR2 may be disposed at a lower portion of the second doped region DR2. After the doping process, the eighth mask layer 118f may be removed.

The eighth mask layer 118f may include or be formed of any of various materials (e.g., a photosensitive material). A patterning process of forming the eighth opening 119f at the eight mask layer 118f may be performed by any of various processes (e.g., a photolithography process). The doping process may be performed by any of various processes (e.g., an ion implantation process or so on). The process of removing the eighth mask layer 118f may be performed by any of various etching processes (e.g., a dry etching process and/or a wet etching process). However, example embodiments are not limited thereto, and various modifications are possible.

As described, in some embodiments, the ground region 120g is formed in the process of doping the first conductivity type dopant to the first connection pattern 152. However, example embodiments are not limited thereto. The ground region 120g may formed in a process separate from the process of doping the first conductivity type dopant to the first connection pattern 152. In some embodiments, the ground region 120g may be formed by a plurality of doping processes.

In some embodiments, the doping process of the first and second gate electrodes 142g and 144g of the plurality of transistors 140, the doping process of the second connection pattern 154, and the doping process of the first connection pattern 152 are sequentially performed. However, example embodiments are not limited thereto. An order of the doping process of the first and second gate electrodes 142g and 144g of the plurality of transistors 140, the doping process of the second connection pattern 154, and the doping process of the first connection pattern 152 may be variously modified.

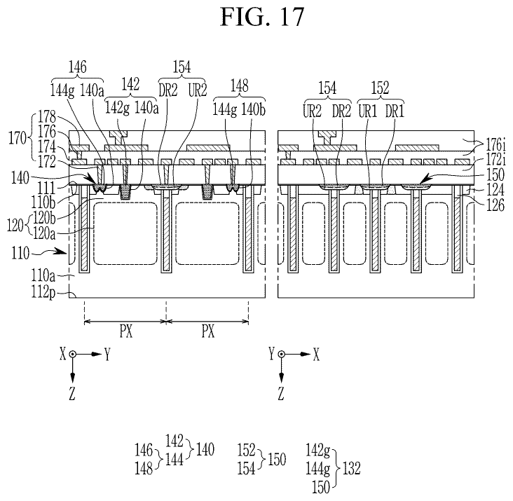

Subsequently, as illustrated in FIG. 17, a wiring portion 170 that is electrically connected to a pixel circuit 130 may be formed on the first surface 111 of the substrate 110. Any of various processes may be applied to the process of forming the wiring portion 170.

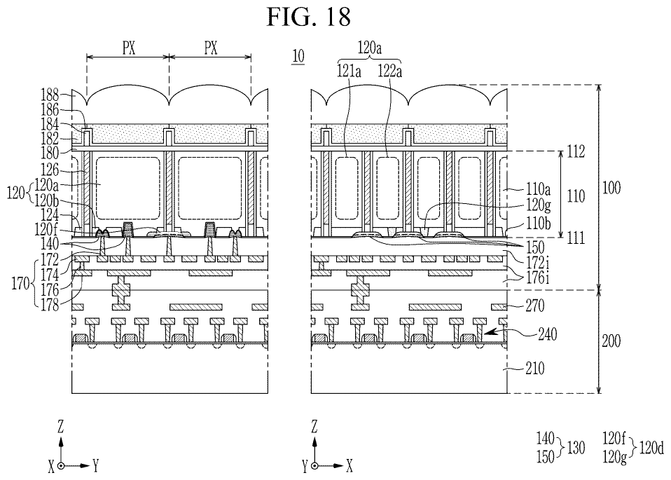

Subsequently, as illustrated in FIG. 18, a partial portion of the substrate 110 may be removed at a side of the preliminary surface 112p (refer to FIG. 17) of the substrate 110. For example, by performing a grinding process, a polishing process, an abrasive process, an etching process, or so on to the preliminary surface 112p of the semiconductor substrate 110a, the partial portion of the substrate 110 may be removed up to a portion where the first isolation portion 126 is disposed. For example, the partial portion of the semiconductor substrate 110a may be removed so that the isolation portion 126 passes through or penetrates a second surface 112 of the substrate 110.

An additional wiring portion 200 may be formed on the first surface 111 of the substrate 110, and a light receiving portion that includes a color filter 182, a micro lens 188, or so on may be formed on the second surface 112 of the substrate 110. For the process of forming the additional wiring portion 200 and/or the process of forming the light receiving portion, any of various processes may be applied. A manufacturing order of the process of forming the additional wiring portion 200 and the process of forming the light receiving portion may be variously modified.

According to an embodiment, the plurality of buried patterns 132 that have three or more structures having a difference in presence or absence of a gate insulation layer or thickness of the gate insulation layer may be formed by an easy process. Accordingly, productivity of the image sensor 10 may be improved and/or enhanced.

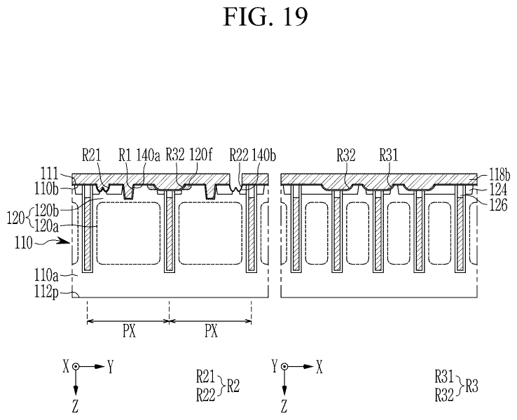

FIG. 19 to FIG. 24 are cross-sectional views that schematically illustrate a manufacturing method of an image sensor according to an embodiment. FIG. 19 to FIG. 24 illustrate a portion corresponding to FIG. 2. To the extent that an element is not described in detail below, it may be understood that the element is at least substantially similar (and/or the same as) to a corresponding element that has been described with reference to FIG. 7 to FIG. 18. A portion which is not described in the above will be described in detail.

As illustrated in FIG. 19, a device isolation portion 124, an isolation portion 126, a photoelectric conversion portion 120, a first recess R1, a second recess R2, and third recess R3 may be formed at a substrate 110, and a first gate insulation layer 140a and/or a second gate insulation layer 140b may be formed. The description on processes with reference to FIG. 7 to FIG. 10 may be applied.

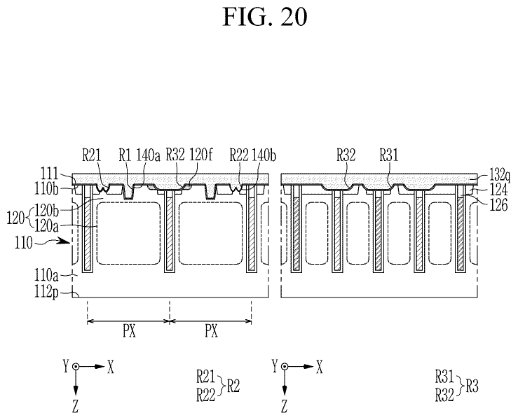

Subsequently, as illustrated in FIG. 20, a doped buried layer 132q may be formed on a first surface 111 of the substrate 110. The doped buried layer 132q may be formed on the first surface 111 of the substrate 110 to fill the first recess R1, the second recess R2, and the third recess R3.

For example, the doped buried layer 132q may include a doped semiconductor layer that includes or is formed of a doped semiconductor material (e.g., doped polycrystalline semiconductor, as an example, doped polycrystalline silicon). The doped semiconductor layer may include a second conductivity type dopant to have a second conductivity type, but example embodiments are not limited thereto. The doped buried layer 132q may be formed by any of various processes (e.g., a deposition process).

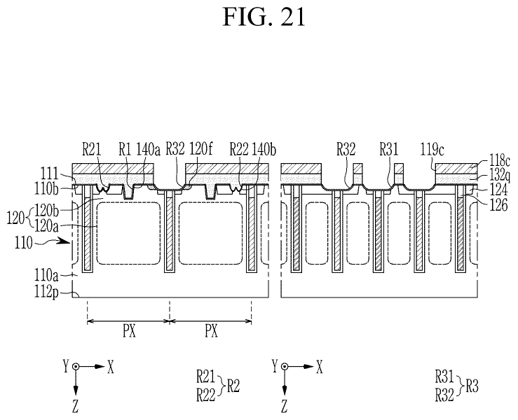

Subsequently, as illustrated in FIG. 21, a portion of the doped buried layer 132q that corresponds to the third recess R3 may be removed. Thereby, the third recess R3 may be exposed.

For example, a fifth mask layer 118c having a fifth opening 119c may be formed on the doped buried layer 132q on the first surface 111 of the substrate 110. The fifth opening 119c of the fifth mask layer 118c may expose a portion corresponding to the third recess R3. A partial portion of the doped buried layer 132q exposed by the fifth opening 119c may be removed. After removing the partial portion of the doped buried layer 132q, the fifth mask layer 118c may be removed.

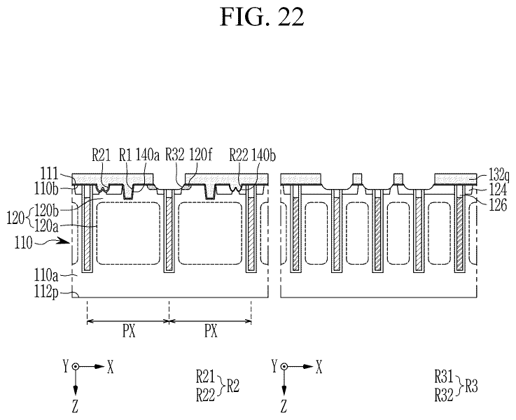

Subsequently, as illustrated in FIG. 22, the first gate insulation layer 140a may be removed in the third recess R3 where the doped buried layer 132q was removed and is exposed to an outside. The process of removing the first gate insulation layer 140a may be performed by an etching process (e.g., a wet etching process). However, example embodiments are not limited thereto, and various modifications are possible.

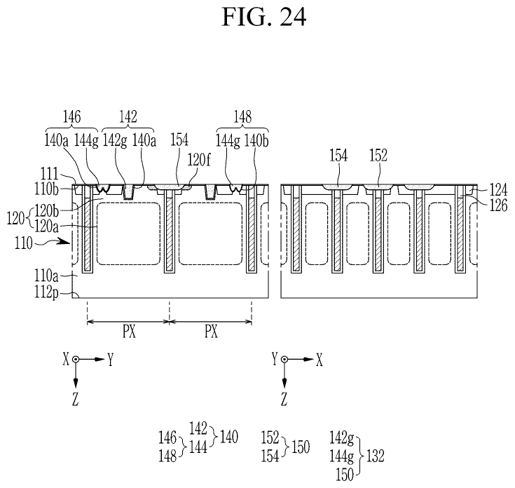

As described above, since the first gate insulation layer 140a may be removed in the third recess R3 after forming the doped buried layer 132q, the doped buried layer 132q may protect the first gate insulation layer 140a or the second gate insulation layer 140b in the first recess R1 and the second recess R2 in the process of removing the first gate insulation layer 140a. Thereby, the first gate insulation layer 140a or the second gate insulation layer 140b may have an improved and/or enhanced property and thus a plurality of transistors 140 (refer to FIG. 24) may have an improved and/or enhanced property.

Subsequently, as illustrated in FIG. 23, an undoped buried layer 132r may be formed on the doped buried layer 132q. The doped buried layer 132r may be formed on the undoped buried layer 132q to fill the third recess R3. Thereby, the buried layer 132p that includes the doped buried layer 132q and the undoped buried layer 132r may be formed.

For example, the undoped buried layer 132r may include an undoped semiconductor material (e.g., undoped polycrystalline semiconductor, as an example, undoped polycrystalline silicon). The undoped buried layer 132q may be formed by any of various processes (e.g., a deposition process).

In an embodiment, in a portion where the first recess R1 and the second recess R2 are disposed, the doped buried layer 132q may fill inside the first recess R1 and the second recess R2, and the undoped buried layer 132q may be disposed on the doped buried layer 132q. In a portion where the third recess R3 is disposed, the undoped buried layer 132r may fill inside the third recess R3

Subsequently, as illustrated in FIG. 24, a portion of the buried layer 132p (refer to FIG. 23) on the first surface 111 of the substrate 110 may be removed to form buried patterns 132. For example, a chemical mechanical polishing process may be performed at a side of the first surface 111 of the substrate 110 to from buried patterns 132 in the first recess R1 (refer to FIG. 23), the second recess R2 (refer to FIG. 23), and the third recess R3 (refer to FIG. 23).

The buried pattern 132 configured to constitute a first gate electrode 142g of the first transistor 142 may be formed in the first recess R1, the buried pattern 132 configured to constitute a second gate electrode 144g of the second transistor 144 may be formed in the second recess R2, and the buried pattern 132 configured to constitute the connection pattern 150 may be formed in the third recess R3. The first gate electrode 142g and the second gate electrode 144g may be formed of the doped buried layer 132q (refer to FIG. 23), and the buried pattern 132 that will constitute the connection pattern 150 may be formed of the undoped buried layer 132r (refer to FIG. 23).

Subsequently, a second conductivity type dopant may be doped into a second connection pattern 154, and/or a first conductivity type dopant may be doped into a first connection pattern 152. The description with reference to FIG. 15 and FIG. 16 may be applied.

Subsequently, a wiring portion 170 may be formed, a partial portion of the substrate 110 at a side of a preliminary surface 112p of the substrate 110 may be removed, and an additional wiring portion 200 and a light receiving portion may be formed. The description with reference to FIG. 17 and FIG. 18 may be applied.

According to an embodiment, the plurality of buried patterns 132 that have three or more structures having a difference in presence or absence of a gate insulation layer or thickness of the gate insulation layer may be formed by an easy process. Further, in the process of removing the first gate insulation layer 140a in the third recess R3 where the connection pattern 150 will be formed, the first gate insulation layer 140a and the second gate insulation layer 140b may be protected to maintain improved and/or enhanced properties. Accordingly, productivity and/or efficiency of the image sensor 10 may be improved and/or enhanced.

Referring to FIG. 25, an image sensor according to an embodiment will be described in detail. To the extent that an element is not described in detail below, it may be understood that the element is at least substantially similar (and/or the same as) to a corresponding element that has been described elsewhere within the present disclosure. A portion which is not described in the above will be described in detail.

FIG. 25 is a plan view that schematically illustrates a substrate included in an image sensor according to an embodiment. FIG. 25 illustrates a portion corresponding to FIG. 3.

Referring to In FIG. 25, in an embodiment, a plurality of buried patterns 132 or a connection pattern 150 may include a wiring pattern 156 that has a buried structure buried in the substrate 110. The wiring pattern 156 may be formed by a process the same as a process of forming a first gate electrode 142g of a first transistor 142, a second gate electrode 144g of a second transistor 144, a first connection pattern 152, and/or a second connection pattern 154.

The wiring pattern 156 may include a base material the same as a base material of the first gate electrode 142g of the first transistor 142, the second gate electrode 144g of the second transistor 144, the first connection pattern 152, and/or the second connection pattern 154. A surface (e.g., an outer surface) of the wiring pattern 156 may include a concave portion that has a shape the same as or similar to a shape of a concave portion formed at a surface (e.g. an outer surface) of the first gate electrode 142g of the first transistor 142, the second gate electrode 144g of the second transistor 144, the first connection pattern 152, and/or the second connection pattern 154. The surface of the wiring pattern 156 may have a surface property the same as the surface property of the first gate electrode 142g of the first transistor 142, the second gate electrode 144g of the second transistor 144, the first connection pattern 152, and/or the second connection pattern 154. The wiring pattern 156 may include a corner portion having a rounded portion that has a shape the same as or similar to a shape of a rounded portion of the first gate electrode 142g of the first transistor 142, the second gate electrode 144g of the second transistor 144, the first connection pattern 152, and/or the second connection pattern 154.

For example, the wiring pattern 156 may connect the second gate electrodes 144g of the second transistors 144 (e.g., a source follower transistors 148a) and the second connection pattern 154 (e.g., a first connection portion 154a) in a first pixel region PX1 and/or a third pixel region PX3. Thereby, a structure of a wiring portion may be simplified and a process of an image sensor may be simplified. Accordingly, productivity of the image sensor may be improved and/or enhanced.

In an embodiment, the wiring pattern 156 may have a second conductivity type to be the same as the second gate electrode 144g and/or the second connection pattern 154. For example, in a doping process of doping the second gate electrode 144g, a doping process of forming source and drain regions of the second transistor 144, and/or a doping process of doping a second conductivity type dopant to the second connection pattern 154, the wiring pattern 156 may be doped together. However, example embodiments are not limited thereto, and various modifications are possible.

In FIG. 25, an example is illustrated where the wiring pattern 156 includes a first wiring portion and a second wiring portion. The first wiring portion may connect the source follower transistor 148a disposed in the first pixel region PX1 and the second connection pattern 154, and the second wiring portion may connect the source follower transistor 148a disposed in the third pixel region PX3 and the second connection pattern 154. However, example embodiments are not limited thereto. For example, the wiring pattern 156 may include one of the first wiring portion and the second wiring portion. In some embodiments, the wiring pattern 156 may include an wiring portion other than the first wiring portion and the second wiring portion. For example, the wiring pattern 156 may include a wiring portion that connects various devices, members, units, elements, or so on included in the image sensor.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate,
wherein the pixel circuit includes a plurality of buried patterns, each of the plurality of buried patterns having a buried structure in the substrate,
wherein the pixel circuit includes a first transistor and a second transistor,
wherein the first transistor includes a first gate electrode and the second transistor includes a second gate electrode,
wherein the first gate electrode is a vertical transfer gate electrode and a cross-sectional shape of the second gate electrode is different from a cross-sectional shape of the first gate electrode, and
wherein the plurality of buried patterns include the first gate electrode and the second gate electrode.

2. The image sensor of claim 1, wherein the plurality of buried patterns include a same base material.

3. The image sensor of claim 1, wherein
the plurality of buried patterns each include a surface,
in each of the plurality of buried patterns, the surface includes a concave portion having a concave shape and including a portion between the first surface of the substrate and the second surface of the substrate, or
the plurality of surfaces of the plurality of buried patterns have a same surface property, or
a corner portion of each of the plurality of buried patterns includes a rounded portion.

4. The image sensor of claim 1, wherein
an inner portion of the second gate electrode is between both of side portions of the second gate electrode, and
the second gate electrode includes a depth change portion where a depth of the inner portion of the second gate electrode is different than a depth of both of the side portions of the second gate electrode.

5. The image sensor of claim 1, further comprising:
device isolation portions at both sides of the second gate electrode.

6. The image sensor of claim 1, wherein
the pixel circuit includes a plurality of second transistors and the second transistor is one of the plurality of second transistors,
the plurality of second transistors are configured to perform different operations in the plurality of pixel regions, and
the plurality of second transistors respectively including a plurality of second gate electrodes having same cross-sectional structures.

7. The image sensor of claim 1, wherein
the pixel circuit includes a source follower transistor and at least one of a reset transistor or a selection transistor,
a thickness of a gate insulation layer of the first transistor or a thickness of a gate insulation layer of the second transistor is greater than a thickness of a gate insulation layer of the source follower transistor, and
the second transistor is the reset transistor or the selection transistor.

8. The image sensor of claim 1, wherein
the plurality of buried patterns include at least one of a doping connection pattern or a wiring pattern,
the doping connection pattern has a buried structure in the substrate and is connected to the substrate or a doping region in the substrate, and
the wiring pattern has a buried structure in the substrate.

9. The image sensor of claim 1, wherein
the substrate includes a doping region,
the doping region includes at least one of a floating diffusion region or a ground region in a portion of the substrate adjacent to the first surface of the substrate,
the plurality of buried patterns include at least one of a first connection pattern connected to the ground region or a second connection pattern connected to the floating diffusion region.

10. The image sensor of claim 9, further comprising
an isolation portion disposed to correspond to a boundary of the plurality of pixel regions,
wherein the first connection pattern or the second connection pattern is in at least two pixel regions of the plurality of pixel regions, and
at least a partial portion of the first connection pattern or the second connection pattern is on the isolation portion.

11. The image sensor of claim 9, further comprising
a wiring portion that is disposed on the first surface of the substrate and includes a first contact via electrically connected to the pixel circuit; and
an isolation portion disposed to correspond to a boundary of the plurality of pixel regions,
wherein at least a partial portion of the first contact via is connected to the first connection pattern or the second connection pattern in a portion overlapping the isolation portion in a plan view.

12. The image sensor of claim 9, wherein
the plurality of pixel regions include a first pixel region, a second pixel region, a third pixel region, and a fourth pixel region,
the first pixel region and the second pixel region are adjacent to each other in a first direction,
the third pixel region and the fourth pixel region that are adjacent to the first pixel region and the second pixel region, respectively, in a second direction,
the second direction crosses the first direction,
the first connection pattern is in the first pixel region, the second pixel region, the third pixel region, and the fourth pixel region and the first connection pattern is connected to ground regions in the first pixel region, the second pixel region, the third pixel region, and the fourth pixel region, respectively,
the second connection pattern includes a first connection portion and a second connection portion,
the first connection portion of the second connection pattern is in the first pixel region and the third pixel region and is connected to floating diffusion regions in the first pixel region and the third pixel region, respectively,
the second connection portion of the second connection pattern is in the second pixel region and the fourth pixel region and is connected to floating diffusion regions in the second pixel region and the fourth pixel region, respectively.

13. The image sensor of claim 1, wherein
the plurality of buried patterns include a connection pattern and a wiring pattern,
wherein the connection pattern has a buried structure in the substrate and is connected to a floating diffusion region adjacent to the first surface of the substrate, and
wherein the wiring pattern connects the second gate electrode of the second transistor to the connection pattern.

14. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate;
wherein the pixel circuit includes a plurality of buried patterns, each of the plurality of buried patterns having a buried structure in the substrate,
wherein the pixel circuit includes a first transistor, a second transistor, and a connection pattern,
wherein the first transistor includes a first gate electrode and the second transistor includes a second gate electrode,
wherein a cross-sectional shape of the second gate electrode is different from a cross-sectional shape of the first gate electrode,
wherein the connection pattern includes at least one of a doping connection pattern or a wiring pattern, and
wherein the plurality of buried patterns include the second gate electrode and the connection pattern.

15. The image sensor of claim 14, wherein
an inner portion of the second gate electrode is between both of side portions of the second gate electrode, and
the second gate electrode includes a depth change portion where a depth of the inner portion of the second gate electrode is different than a depth of both of the side portions of the second gate electrode.

16. The image sensor of claim 14, wherein
the second gate electrode and the connection pattern include a same base material,
a surface of the second gate electrode and a surface of the connection pattern each include a concave portion having a concave shape and including a portion disposed between the first surface of the substrate and the second surface of the substrate; or
the surface of the second gate electrode and the surface of the connection pattern have a same surface property; or
a corner portion of the second gate electrode and a corner portion of the connection pattern each have a rounded portion.

17. The image sensor of claim 14, wherein
the substrate includes a doping region,
the doping region includes at least one of a floating diffusion region or a ground region in a portion of the substrate adjacent to the first surface of the substrate, and
the plurality of buried patterns include at least one of a first connection pattern connected to the ground region or a second connection pattern connected to the floating diffusion region.

18. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate; and
an isolation portion disposed to correspond to a boundary of the plurality of pixel regions,
wherein the pixel circuit includes a doping connection pattern and the doping connection pattern has a buried structure in the substrate and is connected to the substrate or a doping region in the substrate, and
wherein the doping connection pattern is in at least two pixel regions of the plurality of pixel regions, and a portion of the doping connection pattern is on the isolation portion.

19. The image sensor of claim 18,
wherein the doping region includes at least one of a floating diffusion region or a ground region, and
wherein the doping connection pattern includes at least one of a first connection pattern connected to the ground region or a second connection pattern connected to the floating diffusion region.

20. The image sensor of claim 19, wherein
the plurality of pixel regions include a first pixel region, a second pixel region, a third pixel region, and a fourth pixel region,
the first pixel region and the second pixel region are adjacent to each other in a first direction,
the third pixel region and the fourth pixel region are adjacent to the first pixel region and the second pixel region, respectively, in a second direction,
the second direction crosses the first direction,
the first connection pattern is in the first pixel region, the second pixel region, the third pixel region, and the fourth pixel region and is connected to ground regions in the first pixel region, the second pixel region, the third pixel region, and the fourth pixel region, respectively, and
the second connection pattern includes a first connection portion and a second connection portion,
the first connection portion of the second connection pattern is in the first pixel region and the third pixel region and is connected to floating diffusion regions in the first pixel region and the third pixel region, respectively, and
the second connection portion of the second connection pattern is in the second pixel region and the fourth pixel region and is connected to floating diffusion regions in the second pixel region and the fourth pixel region, respectively.
